(19) United States
(12) Patent Application Publication
(10) Pub. No.: US 2025/0174485 A1
(43) Pub. Date: May 29, 2025

(54) SUBSTRATE PROCESSING APPARATUS

(71) Applicant: SCREEN Holdings Co., Ltd., Kyoto (JP)

(72) Inventors: Yuichi TAKAYAMA, Kyoto (JP); Hiroyuki KAWAHARA, Kyoto (JP); Takuya SATO, Kyoto (JP)

(21) Appl. No.: 18/961,939

(22) Filed: Nov. 27, 2024

(30) Foreign Application Priority Data
Nov. 29, 2023 (JP) 2023-202091

(51) Int. Cl. H01L 21/683; G05D 7/06

(52) U.S. Cl. CPC H01L 21/6838; G05D 7/0623

(57) ABSTRACT

A substrate processing apparatus includes: a processing unit that processes a substrate; and a controller that controls the processing unit, wherein the processing unit includes: a plate having an upper surface; a rotation driver that rotates the plate; a support that protrudes upward from the plate, is in contact with at least one of a lower surface of the substrate and an edge of the substrate, and supports the substrate at a position higher than the upper surface of the plate; a gas outlet that is formed on the upper surface of the plate and blows gas upward; a blowing adjuster that adjusts a flow rate of the gas; and a detector that detects a force received from the substrate when a suction force according to Bernoulli's principle acts on the substrate, and the controller controls the processing unit based on information on the force received from the substrate.

### BACKGROUND OF THE INVENTION

### (1) Field of the Invention

The present invention relates to a substrate processing apparatus for processing a substrate. The substrate is, for example, a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, or a solar cell substrate.

### (2) Description of the Related Art

As this type of apparatus, there has conventionally been an apparatus including a substrate conveyance mechanism that conveys a substrate and a processing unit that processes the substrate. The processing unit includes a plate, a rotation driver that rotates the plate, a support that supports the substrate, and a gas outlet that blows gas from an upper surface of the plate. A suction force according to Bernoulli's principle acts on the substrate supported by the support. The processing unit processes the substrate while rotating the substrate in a state where the substrate is held by the suction force. For example, see JP 2021-48362 A.

However, the conventional example having such a configuration has the following problems.

That is, in the conventional apparatus, when the processing unit processes the substrate, the suction force acting on the substrate is not sufficient in some cases. In such a case, there is a problem that the substrate cannot be efficiently processed.

### SUMMARY OF THE INVENTION

As a result of intensive studies, the present inventors have found the following points regarding the suction force acting on the substrate.

That is, the suction force acting on the substrate depends not only on the flow velocity of the gas blown out to the back surface of the substrate and the size (clearance) of the gap between the back surface of the substrate and the upper surface of the plate, but also on the friction coefficient of the support.

As a result of intensive studies, the inventors of the present invention have found the following points as the cause of the insufficient suction force acting on the substrate.

The first cause is a decrease in frictional force generated between the support and the substrate depending on the type of a film (for example, an oxide film) formed on a substrate W. Depending on the type of the film (for example, oxide film) formed on the substrate W, the frictional force between the substrate and the support may decrease. In such a case, even though the suction force acts on the substrate supported by the support, the substrate easily moves with respect to the support. The suction force acting on the substrate supported by the support decreases as the substrate moves more easily.

The second cause is a decrease in frictional force generated between the support and the substrate because of a treating fluid supplied for the back surface processing. The treating fluid is supplied to an upper surface of the substrate supported by the support (the upper surface is referred to as a back surface of the substrate). The treating fluid may flow around the lower surface of the substrate supported by the support. The treating fluid that has flown around the lower surface of the substrate may enter between the support and the substrate. As a result, the frictional force between the support and the substrate may decrease. In such a case, as described above, the suction force acting on the substrate supported by the support decreases.

The present invention has been made in view of such circumstances, and an object thereof is to provide a substrate processing apparatus capable of efficiently processing a substrate.

To achieve such an object, the present invention has the following configuration.

That is, the present invention is a substrate processing apparatus, the apparatus including: a processing unit that processes a substrate; and a controller that controls the processing unit, in which the processing unit includes: a plate having an upper surface; a rotation driver that rotates the plate; a support that protrudes upward from the upper surface of the plate, is in contact with at least one of a lower surface of the substrate and an edge of the substrate, and supports the substrate at a position higher than the upper surface of the plate; a gas outlet that is formed on the upper surface of the plate and blows gas upward; a blowing adjuster that adjusts a flow rate of the gas blown out from the gas outlet; and a detector that detects a force received from the substrate when a suction force according to Bernoulli's principle acts on the substrate supported by the support, and the controller controls the processing unit based on information on the force received from the substrate detected by the detector.

According to the present invention, the support supports the substrate at a position higher than the upper surface of the plate. The gas outlet blows out gas upward from the upper surface of the plate. The blowing adjuster adjusts the flow rate of the gas blown out from the gas outlet. This causes a suction force according to Bernoulli's principle to act on the substrate supported by the support. The detector detects a force received from the substrate when a suction force according to Bernoulli's principle acts on the substrate supported by the support. The controller controls the processing unit based on the information on the force received from the substrate detected by the detector. That is, when the frictional force between the substrate and the support has decreased, the force received from the substrate when the suction force according to the Bernoulli's principle acts on the substrate supported by the support does not sufficiently act on the substrate. Detecting the force received from the substrate with the detector makes it possible for the controller to detect a decrease in the frictional force between the substrate and the support. The controller, which controls the processing unit based on the information on the detected force received from the substrate, can reduce the event that may occur based on the decrease in the frictional force between the substrate and the support. As a result, the substrate can be efficiently processed.

In the present invention, it is preferable that the detector detects a pressing force with which the substrate presses the support when the suction force acts on the substrate supported by the support as the force received from the substrate, and the controller controls the processing unit based on information on the pressing force detected by the detector. When the frictional force between the substrate and the support has decreased, the pressing force with which the substrate presses the support when the suction force according to the Bernoulli's principle acts on the substrate supported by the support does not sufficiently act on the substrate. Detecting the pressing force with which the substrate presses the support with the detector makes it possible for the controller to reliably detect a decrease in the frictional force between the substrate and the support. The controller, which controls the processing unit based on the information on the detected pressing force with which the substrate presses the support, can further reduce the event that may occur based on the decrease in the frictional force between the substrate and the support.

In the present invention, the detector is preferably attached to the support. With this configuration, the force received from the substrate can be accurately detected by the support as the pressing force with which the substrate presses the support.

In the present invention, it is preferable that the detector detects a pressing force with which the support presses the plate when the suction force acts on the substrate supported by the support as the force received from the substrate, and the controller controls the processing unit based on information on the pressing force detected by the detector. With this configuration, the force received from the substrate can be detected based on the pressing force with which the support presses the plate.

In the present invention, the detector is preferably attached to the plate. With this configuration, the force received from the substrate can be detected as the pressing force with which the support presses the plate from a portion different from the support.

In the present invention, the controller preferably changes the flow rate of the gas blown out from the gas outlet based on information on the force received from the substrate. Here, depending on the state of the surface of the substrate to be processes by the processing unit and the flow rate and type of gas or liquid supplied to the upper surface or the lower surface of the substrate by the processing unit, the force received from the substrate is not sufficient for the force required for the processing in some cases. In such a case, the force received from the substrate can be made the force necessary for the processing.

In the present invention, when the force received from the substrate is less than a specified value, the controller preferably adjusts the flow rate of the gas blown out from the gas outlet such that the force received from the substrate is equal to or larger than a specified value. This allows the force received from the substrate to be a force necessary for the processing when the force received from the substrate does not exceed the specified value because of the decrease in the frictional force between the support and the substrate.

In the present invention, the specified value is preferably a value determined in advance for the processing unit to start processing on the substrate. This allows the force received from the substrate to be a force necessary for the processing when the detected force received from the substrate does not exceed the specified value for the processing unit to start the processing on the substrate.

In the present invention, the specified value is preferably a value determined in advance necessary for processing on the substrate when the processing unit is executing the processing on the substrate. This allows the force received from the substrate to be a force necessary for the processing when the detected force received from the substrate has fallen below the specified value necessary for the processing on the substrate when the processing unit is executing the processing on the substrate.

In the present invention, it is preferable that the processing on the substrate includes at least first processing and second processing subsequent to the first processing, and the specified value is a value determined in advance necessary for the second processing when the processing on the substrate is changed from the first processing to the second processing. This allows the force received from the substrate to be a force necessary for the processing when the detected force received from the substrate has fallen below the specified value necessary for the second processing when the processing on the substrate changes from the first processing to the second processing.

In the present invention, the specified value is preferably a value determined in advance for a type of a shape of the substrate. This makes it possible to determine whether the detected force received from the substrate has exceeded a specified value with height according to the shape of the substrate.

In the present invention, the specified value is preferably a value determined in advance according to a rotation speed of the plate. This makes it possible to determine whether the detected force received from the substrate has exceeded a specified value with height according to the rotation speed of the plate.

In the present invention, when the rotation speed of the plate changes during processing in the processing unit, the specified value preferably changes according to a change in the rotation speed of the plate. This makes it possible to determine whether the detected force received from the substrate has exceeded a specified value with height according to the change in rotation speed of the plate.

In the present invention, it is preferable that the substrate is formed with a processing film, the support supports a surface on which the processing film is formed, and the specified value is a value determined in advance according to a type of the processing film. This makes it possible to determine whether the detected force received from the substrate has exceeded a specified value with height according to the type of the processing film.

In the present invention, it is preferable that the apparatus includes a supply part that supplies a treating fluid to the substrate supported by the support, in which the specified value is a value determined in advance according to a type of the treating fluid or a flow rate of the treating fluid. This makes it possible to determine whether the detected force received from the substrate has exceeded a specified value with height according to the type of the treating fluid or the flow rate of the treating fluid.

In the present invention, when the type of the treating fluid or the flow rate of the treating fluid changes during processing in the processing unit, the specified value preferable changes according to a change in the type of the treating fluid or the flow rate of the treating fluid. This makes it possible to determine whether the detected force received from the substrate has exceeded a specified value with height according to the change in the type of the treating fluid or the flow rate of the treating fluid.

In the present invention, the specified value is preferably a value determined in advance according to a type of the processing unit. This makes it possible to determine whether the detected force received from the substrate has exceeded a specified value with height according to the type of the processing unit.

In the present invention, when the force received from the substrate is less than the specified value though the flow rate of the gas blown out from the gas outlet is adjusted to have a value equal to or larger than the specified value, the controller preferably stops a rotation of the rotation driver. Here, the reason of the force received from the substrate being less than the specified value though the flow rate of the gas blown out from the gas outlet is adjusted to be equal to or larger than the specified value may be that the substrate is not supported by the support or the substrate supported by the support is damaged. In such a case, it is possible to reduce unnecessary processing time by stopping the rotation of the rotation driver.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a plan view of a substrate processing apparatus according to a first embodiment;

FIG. 2 is a control block diagram of the substrate processing apparatus;

FIG. 3 is a plan view of a substrate;

FIG. 4A is a sectional view of a normal substrate, and FIG. 4B is a sectional view of a special substrate;

FIG. 5 is a diagram schematically illustrating a configuration of a processing unit;

FIG. 6 is a plan view of a plate;

FIG. 7 is a sectional view of the plate taken along the line B-B;

FIG. 8 is a flowchart illustrating a procedure of control of a controller and operation of a processing unit according to the first embodiment;

FIG. 9A is a graph illustrating a temporal change in the force received from the substrate according to the first embodiment;

FIG. 9B is a graph illustrating a temporal change in the adjusted blowing amount according to the first embodiment;

FIG. 10A is a graph illustrating a temporal change in the force received from the substrate according to the first embodiment different from FIG. 9A;

FIG. 10B is a graph illustrating a temporal change in the adjusted blowing amount according to the first embodiment different from FIG. 9B;

FIG. 11A is a graph illustrating a temporal change in the force received from the substrate according to the first embodiment different from FIGS. 9A and 10A;

FIG. 11B is a graph illustrating a temporal change in the adjusted blowing amount according to the first embodiment different from FIGS. 9B and 10B;

FIG. 12 is a flowchart illustrating a procedure of control of a controller and operation of a processing unit according to a second embodiment;

FIG. 13 is a flowchart illustrating a procedure of control of a controller and operation of a processing unit according to a third embodiment;

FIG. 14 is a flowchart illustrating a procedure of control of a controller and operation of a processing unit according to a fourth embodiment;

FIG. 15A is a graph illustrating a temporal change in the force received from the substrate according to the fourth embodiment;

FIG. 15B is a graph illustrating a temporal change in the adjusted blowing amount according to the fourth embodiment;

FIG. 16 is a flowchart illustrating a procedure of control of a controller and operation of a processing unit according to a fifth embodiment;

FIG. 17 is a flowchart illustrating a procedure of control of a controller and operation of a processing unit according to a sixth embodiment; and

FIG. 18 is a plan view of a plate according to a modification.

### DESCRIPTION OF THE PREFERRED EMBODIMENTS

Hereinafter, preferred examples of the present invention will be described in detail with reference to the drawings.

### First Embodiment

### <Outline of Substrate Processing Apparatus>

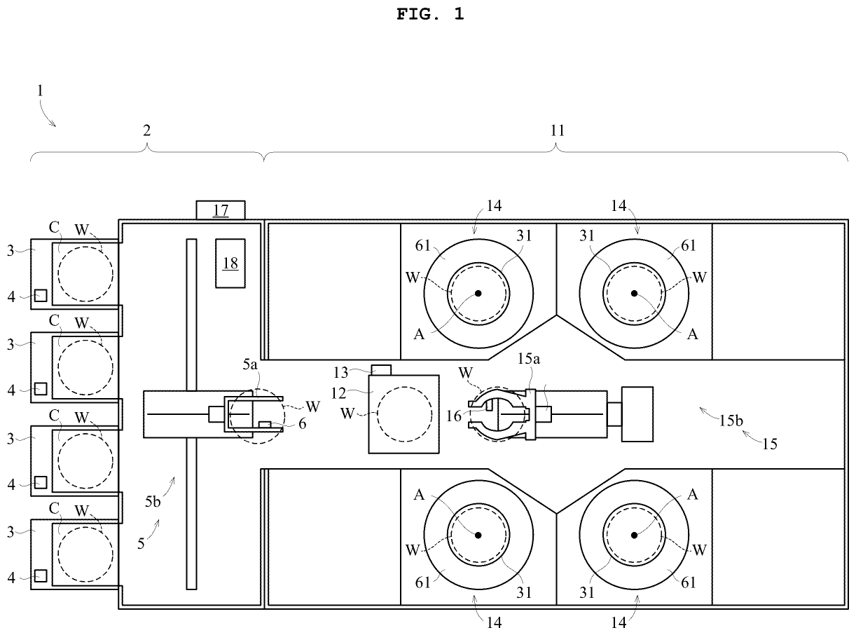

FIG. 1 is a plan view of a substrate processing apparatus according to a first embodiment. A substrate processing apparatus 1 processes a substrate (for example, a semiconductor wafer) W.

The substrate W is, for example, a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, or a solar cell substrate.

The substrate processing apparatus 1 includes an indexer 2. The indexer 2 includes a plurality of (for example, four) carrier placement parts 3. Each carrier placement part 3 places one carrier C. The carrier C accommodates a plurality of substrates W. The carrier C is, for example, a front opening unified pod (FOUP).

The carrier C has a barcode (not illustrated). The barcode is an identifier for identifying the carrier C or identifying the substrate W in the carrier C. The barcode is attached to the outer surface of the carrier C, for example.

The indexer 2 includes a barcode reader 4. The barcode reader 4 reads the barcode attached to the carrier C placed on the carrier placement part 3. The barcode reader 4 is attached to the carrier placement part 3, for example.

The indexer 2 includes a conveyance mechanism 5. The conveyance mechanism 5 can access the carrier C placed on each carrier placement part 3. The conveyance mechanism 5 conveys the substrate W to the carrier C placed on the carrier placement part 3. The conveyance mechanism 5 includes a hand 5a and a hand driver 5b. The hand 5a supports one substrate W in a horizontal orientation. The hand driver 5b is coupled to the hand 5a. The hand driver 5b moves the hand 5a. For example, the hand driver 5b moves the hand 5a in parallel in a horizontal direction. For example, the hand driver 5b moves the hand 5a in parallel in a vertical direction. For example, the hand driver 5b rotationally moves the hand 5a about a rotation axis. The rotation axis of the hand 5a is, for example, parallel to the vertical direction.

The indexer 2 includes a presence/absence detector 6. The presence/absence detector 6 detects whether the hand 5a is supporting the substrate W. That is, the presence/absence detector 6 detects whether the conveyance mechanism 5 is conveying the substrate W. The presence/absence detector 6 is attached to the hand 5a, for example.

The substrate processing apparatus 1 includes a processing block 11. The processing block 11 is connected to the indexer 2.

The processing block 11 includes a placement part 12. A plurality of substrates W are placed on the placement part 12.

The processing block 11 includes a shape detector 13. The shape detector 13 detects the shape of the substrate W placed on the placement part 12. The shape detector 13 is, for example, an image sensor that images the substrate W. The image sensor is, for example, a one-dimensional image sensor or a two-dimensional image sensor. The shape detector 13 is attached to the placement part 12, for example.

The processing block 11 includes a plurality of processing units 14. Each processing unit 14 processes one substrate W.

The processing block 11 includes a conveyance mechanism 15. The conveyance mechanism 15 can access the placement part 12 and all the processing units 14. The conveyance mechanism 15 conveys the substrate W to the placement part 12 and the processing units 14. The conveyance mechanism 15 includes a hand 15a and a hand driver 15b. The hand 15a supports one substrate W in a horizontal orientation. The hand driver 15b is coupled to the hand 15a. The hand driver 15b moves the hand 15a. For example, the hand driver 15b moves the hand 15a in parallel in a horizontal direction. For example, the hand driver 15b moves the hand 15a in parallel in a vertical direction. For example, the hand driver 15b rotationally moves the hand 15a about a rotation axis. The rotation axis of the hand 15a is, for example, parallel to the vertical direction.

The processing block 11 includes a presence/absence detector 16. The presence/absence detector 16 detects whether the hand 15a is supporting the substrate W. That is, the presence/absence detector 16 detects whether the conveyance mechanism 15 is conveying the substrate W. The presence/absence detector 16 is attached to the hand 15a, for example.

The placement part 12 is disposed between the conveyance mechanism 5 and the conveyance mechanism 15. The conveyance mechanism 5 can also access the placement part 12. The conveyance mechanism 5 conveys the substrate W to the placement part 12. The substrate W conveyed between the conveyance mechanism 5 and the conveyance mechanism 15 is placed on the placement part 12.

The substrate processing apparatus 1 includes an input part 17. The user can input information to the input part 17. The input part 17 is attached to, for example, the outer surface of the indexer 2.

The substrate processing apparatus 1 includes a controller 18. The controller 18 acquires detection results of the barcode reader 4, the presence/absence detectors 6 and 16, and the shape detector 13. The controller 18 acquires information input to the input part 17. The controller 18 controls the conveyance mechanisms 5 and 15 and the processing unit 14. Specifically, the controller 18 controls the hand driver 5b of the conveyance mechanism 5 and the hand driver 15b of the conveyance mechanism 15.

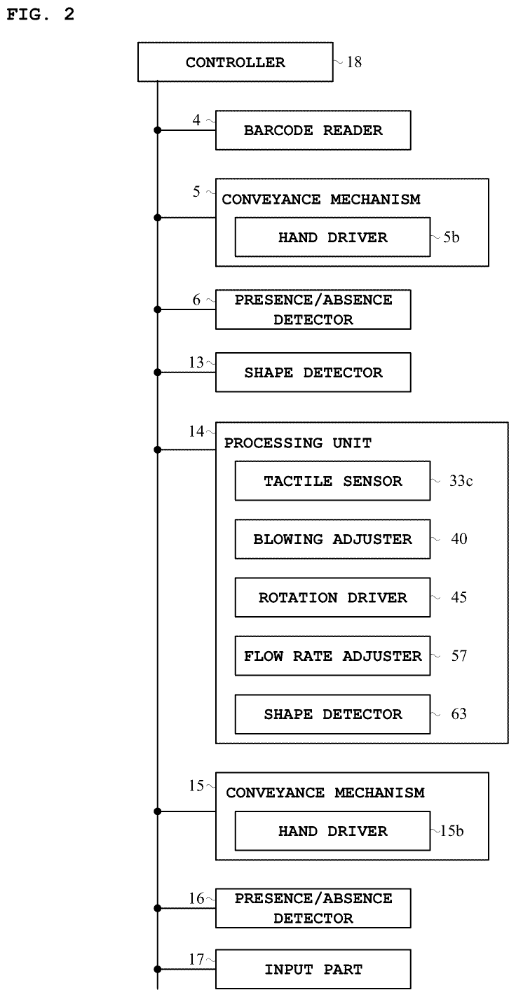

FIG. 2 is a control block diagram of the substrate processing apparatus 1. The controller 18 is communicably connected to the barcode reader 4, the conveyance mechanisms 5 and 15, the presence/absence detectors 6 and 16, the shape detector 13, the processing unit 14, and the input part 17.

The controller 18 is realized by a central processing unit (CPU) that executes various types of processing, a random-access memory (RAM) that is a work area of arithmetic processing, a storage medium such as a fixed disk, and the like. The storage medium stores various types of information in advance. The storage medium stores, for example, information on operating conditions of the conveyance mechanisms 5 and 15. The storage medium stores, for example, a processing recipe (processing program) for processing the substrate W. The processing recipe defines processing conditions of the processing unit 14. The storage medium stores, for example, information for identifying each substrate W.

An operation example of the substrate processing apparatus 1 will be described. The conveyance mechanism 5 conveys the substrate W from the carrier C on the carrier placement part 3 to the placement part 12. The conveyance mechanism 15 conveys the substrate W from the placement part 12 to the processing unit 14. The processing unit 14 processes the substrate W. The conveyance mechanism 15 conveys the substrate W from the processing unit 14 to the placement part 12. The conveyance mechanism 5 conveys the substrate W from the placement part 12 to the carrier C on the carrier placement part 3.

### <Shape of Substrate W>

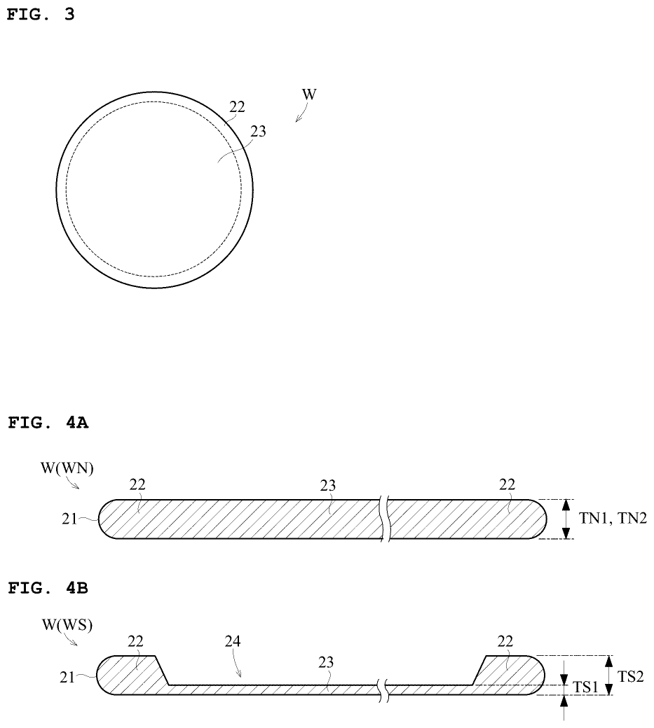

FIG. 3 is a plan view of the substrate W. A basic shape of the substrate W will be described. The substrate W has a thin flat plate shape. The substrate W has a substantially circular shape in plan view. The substrate W has a peripheral edge 22 and a main portion 23. The main portion 23 is a portion of the substrate W positioned inside the peripheral edge 22. A semiconductor device is formed in the main portion 23. In FIG. 3, a boundary between the peripheral edge 22 and the main portion 23 is indicated by a broken line for convenience.

The substrate processing apparatus 1 can process substrates W having different shapes. Hereinafter, two types of substrates W having different shapes will be exemplified. For convenience, two types of substrates W having different shapes are referred to as a normal substrate WN and a special substrate WS, respectively. FIG. 4A is a sectional view of the normal substrate WN. The normal substrate WN is a substrate W not including a recess 24 described later.

FIG. 4B is a sectional view of the special substrate WS. The special substrate WS is a substrate W including a recess 24 formed by the main portion 23 being recessed more than the peripheral edge 22. The recess 24 is formed by, for example, a grinding processing.

The main portion 23 of the special substrate WS is thinner than the main portion 23 of the normal substrate WN. The special substrate WS has lower rigidity than the normal substrate WN. The special substrate WS warps more easily than the normal substrate WN.

Specifically, the main portion 23 of the normal substrate WN has a thickness TN1. The main portion 23 of the special substrate WS has a thickness TS1. The thickness TS1 is smaller than the thickness TN1. The thickness TS1 is, for example, 10 [μm] or more and 200 [μm] or less. The thickness TN1 is, for example, 600 [μm] or more and 1000 [μm] or less.

The peripheral edge 22 of the normal substrate WN has a thickness TN2. The peripheral edge 22 of the special substrate WS has a thickness TS2. The thickness TN2 is, for example, the same as the thickness TS2. The thicknesses TN2 and TS2 are, for example, 600 [μm] or more and 1000 [μm] or less.

### <Configuration of Processing Unit 14>

See FIG. 1. The processing unit 14 includes a substrate holder 31 and a guard 61. The substrate holder 31 holds one substrate W. The substrate holder 31 holds the substrate W in a horizontal orientation. The guard 61 is disposed so as to surround the side of the substrate holder 31.

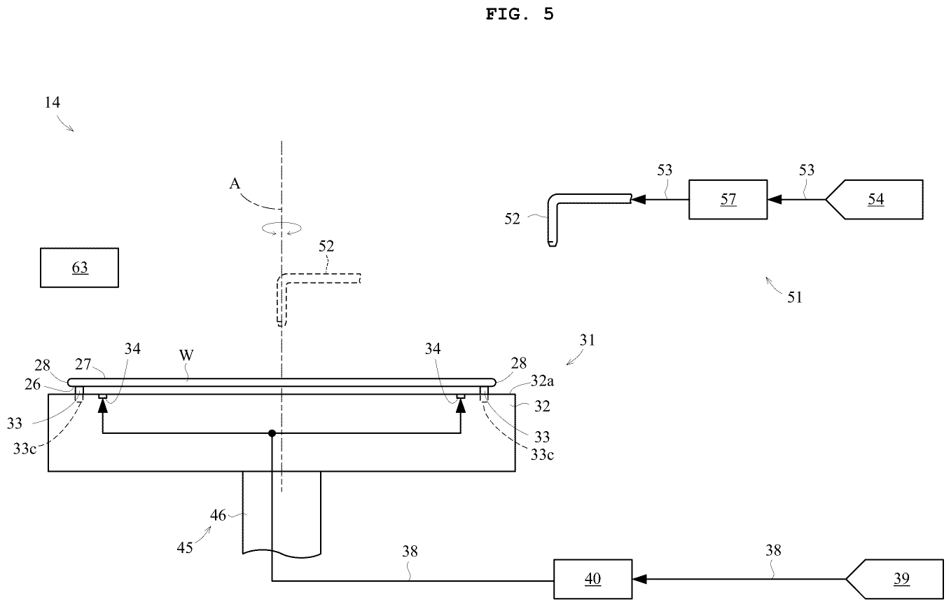

FIG. 5 is a diagram schematically illustrating a configuration of the processing unit 14. FIG. 5 omits illustration of the guard 61. The processing unit 14 further includes a rotation driver 45 and a treating fluid supply part 51. The rotation driver 45 rotates the substrate holder 31. The treating fluid supply part 51 supplies the treating fluid to the substrate W held by the substrate holder 31. The guard 61 receives the treating fluid scattered from the substrate W.

The substrate holder 31 includes a plate 32. The plate 32 has a substantially disk shape. The plate 32 has an upper surface 32a. The upper surface 32a is substantially horizontal. The upper surface 32a is substantially flat.

The rotation driver 45 is coupled to the lower portion of the plate 32. The rotation driver 45 rotates the plate 32 about a rotation axis A. The rotation axis A is parallel to the vertical direction. The rotation driver 45 passes through the center of the plate 32. More specifically, the rotation driver 45 includes a rotation shaft 46. The rotation shaft 46 extends in the vertical direction. The rotation shaft 46 is disposed on the rotation axis A. The rotation shaft 46 is connected to a lower portion of the plate 32. The rotation driver 45 further includes a motor (not illustrated). The motor is coupled to the rotation shaft 46. The motor rotates the rotation shaft 46 about the rotation axis A.

The rotation driver 45 can further change the rotation speed of the substrate holder 31 (plate 32).

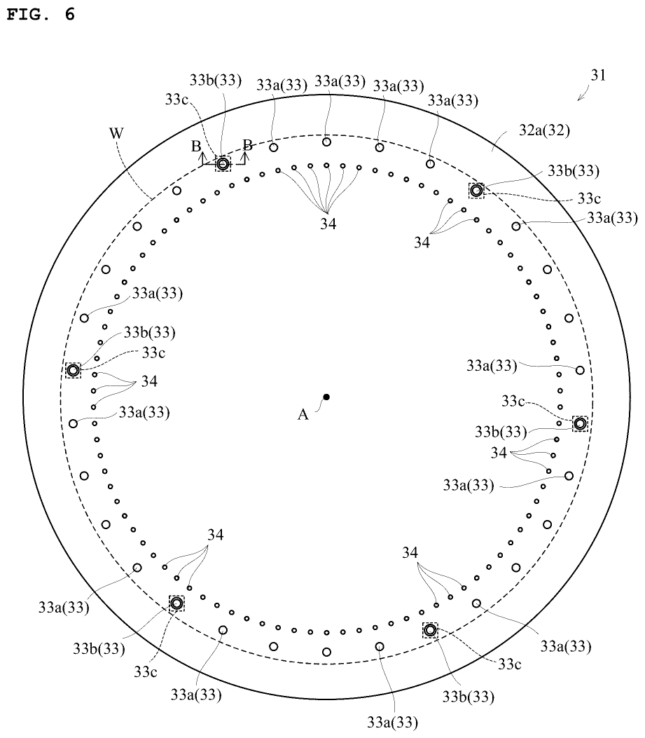

FIG. 6 is a plan view of the substrate 32. The upper surface 32a of the plate 32 is circular in plan view. The upper surface 32a of the plate 32 is larger than the substrate W in plan view.

The substrate holder 31 includes a plurality of (for example, 30) fixing pins 33. The fixing pins 33 support the substrate W. Each fixing pin 33 is fixed to the plate 32. Each fixing pin 33 cannot move with respect to the plate 32 with the following exceptions.

Each fixing pin 33 is divided into a fixing pin 33a and a fixing pin 33b. Each fixing pin 33a cannot move with respect to the plate 32. Each fixing pin 33a cannot rotate with respect to the plate 32. On the other hand, each fixing pin 33b is slightly movable in the vertical direction with respect to the plate 32 because of the action of an elastic member 33c4 of a tactile sensor 33c described later. The tactile sensor 33c is disposed inside the plate 32 as described later. A part of the tactile sensor 33c may be exposed from the plate 32. Each fixing pin 33b cannot move in a direction parallel to the upper surface 32a of the plate 32. Each fixing pin 33b cannot move in a direction oblique to the upper surface 32a of the plate 32.

The fixing pins 33 are disposed on the upper surface 32a of the plate 32. The fixing pins 33 are disposed on the peripheral edge of the upper surface 32a of the plate 32. The fixing pins 33 are arrayed on a circumference around the rotation axis A in plan view. The fixing pins 33 are separated from each other.

Six fixing pins 33b are disposed at predetermined angles (for example, 60 degrees). Six fixing pins 33b are disposed at predetermined intervals (for example, a distance of four pins). All the fixing pins 33 may be the fixing pins 33b. For example, when only six fixing pins 33 are disposed, all the six fixing pins 33 may be fixing pins 33b.

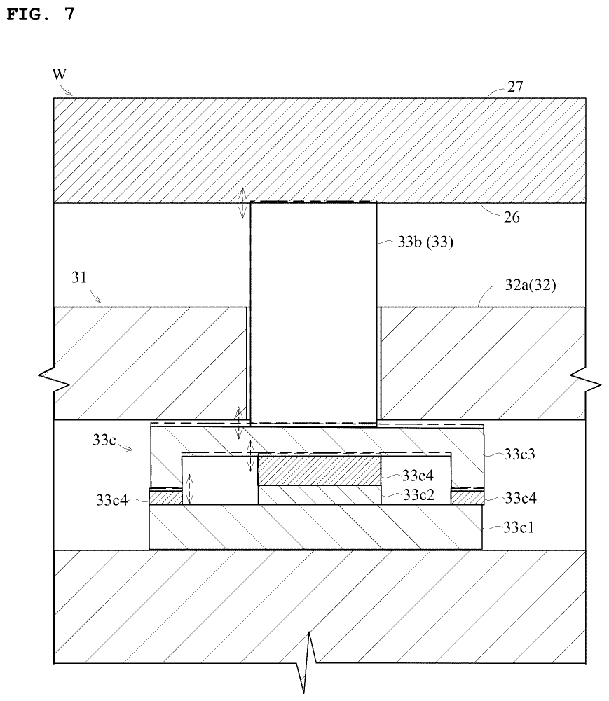

FIG. 7 is a sectional view of the plate 32 taken along the line B-B. For the fixing pin 33b and the plate 32, a space is formed below the fixing pin 33b illustrated in FIG. 6 to accommodate the base end of the fixing pin 33b and the tactile sensor 33c. The tactile sensor 33c is fixed to the lower surface of the space, and the base end of the fixing pin 33b is fixed to the upper surface of the tactile sensor 33c. The tip of the fixing portion 33b is exposed from the upper surface 32a of the plate 32.

When the substrate W is placed on the fixing pin 33, the tactile sensor 33c detects the force in the vertical direction generated because of the placement of the substrate W. When the substrate W is not placed on the fixing pin 33, the tactile sensor 33c does not detect the force in the vertical direction. As will be described later, the tactile sensor 33c detects the force that the fixing pin 33 receives from the substrate W in the vertical direction when a suction force according to the Bernoulli's principle acts on the substrate W placed on the fixing pin 33. That is, the tactile sensor 33c detects, as a force received from the substrate W, a pressing force with which the substrate W presses the fixing pin 33 when a suction force acts on the substrate W supported by the fixing pin 33. The force N received from the substrate W is a force in the vertical direction generated when the substrate W pushes the fixing pin 33b with the suction force.

The tactile sensor 33c includes a base material 33cl fixed to the lower surface of the space, a sensor chip 33c2 fixed to the base material 33cl, a cover 33c3 covering the sensor chip 33c2, and an elastic member 33c4 interposed between the cover, the base material 33cl, and the sensor chip 33c2. The fixing pin 33b is fixed to the upper surface of the cover 33c3. The sensor chip 33c2 is, for example, a piezoresistive MEMS sensor that uses a piezoresistive effect. The sensor chip 33c2 detects a force applied in the vertical direction.

In a state where the substrate W is not placed on the fixing pin 33, the height of the exposed fixing pin 33b is slightly higher than the height of the fixing pin 33a. In a state where the substrate W is placed on the fixing pin 33, the height of the exposed fixing pin 33b and the height of the exposed fixing pin 33a are the same or almost the same.

See FIG. 5. The fixing pin 33 protrudes upward from the upper surface 32a of the plate 32. The fixing pin 33 is in contact with the lower surface 26 of the substrate W. More specifically, the fixing pin 33 is in contact with the lower surface 26 at the peripheral edge 22 of the substrate W. This causes the fixing pin 33 to support the substrate W at a position higher than the upper surface 32a of the plate 32. In FIG. 6, the fixing pin 33a, the cover 33c3, and the elastic member 33c4 in a state where the substrate W is not supported are indicated by two-dot chain lines. When the fixing pin 33 supports the substrate W, the center of the substrate W is positioned on the rotation axis A.

The fixing pin 33 is not in contact with an upper surface 27 of the substrate W. The fixing pin 33 allows the substrate W to move upward with respect to the fixing pin 33. The fixing pin 33 is not in contact with an edge 28 of the substrate W. The fixing pin 33 itself allows the substrate W to slide with respect to the fixing pin 33. In this manner, the fixing pin 33 itself does not hold the substrate W.

The substrate holder 31 includes a gas outlet 34. The gas outlet 34 is formed in the upper surface 32a of the plate 32. The gas outlet 34 is disposed at a position overlapping the substrate W supported by the fixing pin 33 in plan view. The gas outlet 34 is disposed below the substrate W supported by the fixing pin 33. The gas outlet 34 blows out gas from the position below the substrate W supported by the fixing pin 33. The gas outlet 34 blows out gas upward. The gas outlet 34 blows out gas between the upper surface 32a of the plate 32 and the lower surface 26 of the substrate W supported by the fixing pin 33. The gas blown out from the gas outlet 34 is, for example, nitrogen gas or air. The gas blown out from the gas outlet 34 is, for example, a high-pressure gas or a compressed gas. The gas is supplied between the upper surface 32a of the plate 32 and the lower surface 26 of the substrate W supported by the fixing pin 33. The gas flows along the lower surface 26 of the substrate W supported by the fixing pin 33. This causes the gas outlet 34 to suck the substrate W. Specifically, a negative pressure is formed by the gas flowing along the lower surface 26 of the substrate W. That is, the air pressure received by the lower surface 26 of the substrate W is smaller than the air pressure received by the upper surface 27 of the substrate W. Because of the Bernoulli's principle, a downward force acts on the substrate W. That is, the substrate W is sucked downward. The substrate W is sucked toward the gas outlet 34 and the plate 32. However, the gas outlet 34 is not in contact with the substrate W. The plate 32 is not in contact with the substrate W either.

The gas outlet 34 sucks the substrate W downward, the fixing pin 33 comes into contact with the lower surface 26 of the substrate W, and thus the substrate W is supported and held at a predetermined position. Normally, the substrate W does not slide in the horizontal direction with respect to the fixing pin 33 because of the suction force acting on the substrate W. However, as will be described later, when the frictional force between the substrate W and the fixing pin 33 decreases, the substrate W easily slides in the horizontal direction with respect to the fixing pin 33.

As the flow rate of the gas blown out from the gas outlet 34 increases, the suction force acting on the substrate W increases. However, as will be described later, when the frictional force between the substrate W and the fixing pin 33 decreases, the substrate W easily slides in the horizontal direction with respect to the fixing pin 33 even though the flow rate of the gas blown out from the gas outlet 34 is increased.

Thus, the present invention effectively detects a decrease in frictional force between the substrate W and the fixing pin 33, and prevents an event in which the substrate W slides in the horizontal direction with respect to the fixing pin 33 in advance. Even though the substrate W starts to slide in the horizontal direction with respect to the fixing pin 33, the substrate W is stopped from sliding in the horizontal direction with respect to the fixing pin 33 as early as possible.

The fixing pin 33 is an example of the support in the present invention. The tactile sensor 33c is an example of the detector in the present invention.

The processing unit 14 includes a gas supply path 38. The gas supply path 38 supplies gas to the gas outlet 34.

The gas supply path 38 includes a first end and a second end. The first end of the gas supply path 38 is connected to the gas outlet 34. The second end of the gas supply path 38 is connected to a gas supply source 39. A part of the gas supply path 38 is formed inside the plate 32. The gas supply path 38 supplies gas to the gas outlet 34.

The processing unit 14 includes a blowing adjuster 40. The blowing adjuster 40 is provided in the gas supply path 38. The blowing adjuster 40 adjusts the flow rate of the gas blown out from the gas outlet 34. The blowing adjuster 40 includes, for example, a flow rate regulating valve and an on-off valve.

The treating fluid supply part 51 includes a nozzle 52. The nozzle 52 discharges a treating fluid. The nozzle 52 supplies the treating fluid to the upper surface 27 of the substrate W supported by the fixing pin 33. The nozzle 52 is disposed at a position higher than the substrate W supported by the fixing pin 33. The nozzle 52 discharges the treating fluid downward.

The processing unit 14 includes a nozzle moving mechanism (not illustrated). The nozzle moving mechanism moves the nozzle 52 to a processing position and a retraction position. FIG. 5 illustrates the nozzle 52 in the processing position in dashed lines. FIG. 5 illustrates the nozzle 52 in the processing position in a solid line. The processing position is a position above the substrate W supported by the fixing pin 33. When the nozzle 52 is at the processing position, the nozzle 52 overlaps the substrate W supported by the fixing pin 33 in plan view. When the nozzle 52 is at the retraction position, the nozzle 52 does not overlap the substrate W supported by the fixing pin 33 in plan view.

The treating fluid supply part 51 includes a pipe 53. The pipe 53 supplies the treating fluid to the nozzle 52. The pipe 53 includes a first end and a second end. The first end of the pipe 53 is connected to the nozzle 52. The second end of the pipe 53 is connected to a treating fluid supply source 54.

The processing unit 14 includes a flow rate adjuster 57. The flow rate adjuster 57 is provided in the pipe 53. The flow rate adjuster 57 adjusts the flow rate of the treating fluid supplied to the substrate W by the treating fluid supply part 51. That is, the flow rate adjuster 57 adjusts the flow rate of the treating fluid discharged from the nozzle 52.

The processing unit 14 includes a shape detector 63. The shape detector 63 detects the shape of the substrate W supported by the fixing pin 33. The shape detector 63 is, for example, an image sensor that images the substrate W. The image sensor is, for example, a one-dimensional image sensor or a two-dimensional image sensor. The shape detector 63 is disposed above the plate 32, for example. The shape detector 63 is disposed above the substrate W supported by the fixing pin 33, for example.

See FIG. 2. The controller 18 acquires detection results of the tactile sensor 33c and the shape detector 63 in the processing unit 14. The controller 18 controls the blowing adjuster 40, the rotation driver 45, and the flow rate adjuster 57 based on the processing recipe. In particular, the controller 18 controls the blowing adjuster 40, the rotation driver 45, and the flow rate adjuster 57 based on information on the force received from the substrate W detected by the tactile sensor 33c. The controller 18 controls a nozzle moving mechanism (not illustrated).

### <Operation Example of Processing Unit 14 of First Embodiment>

In the operation example of the processing unit 14 of the following embodiment, the controller 18 changes the flow rate of the gas blown out from the gas outlet 34 based on the information of the force N received from the substrate W detected by the tactile sensor 33c via the fixing pin 33b during the operation of the processing unit 14. The term “during the operation of the processing unit 14” means a period during which a suction force according to Bernoulli's principle acts on the substrate W placed on the fixing pin 33. In particular, in the operation example of the processing unit 14 of the first embodiment, the controller 18 adjusts the flow rate of the gas so that the force N received from the substrate W detected by the tactile sensor 33c via the fixing pin 33b during the operation of the processing unit 14 becomes equal to or larger than a specified value determined in advance according to the shape of the substrate W (for example, the thickness of the main portion 23) when the force N is less than the specified value. In the first embodiment, the flow rate of the gas is determined in advance according to the shape of the substrate W, and the flow rate of the gas is determined in advance as a reference value.

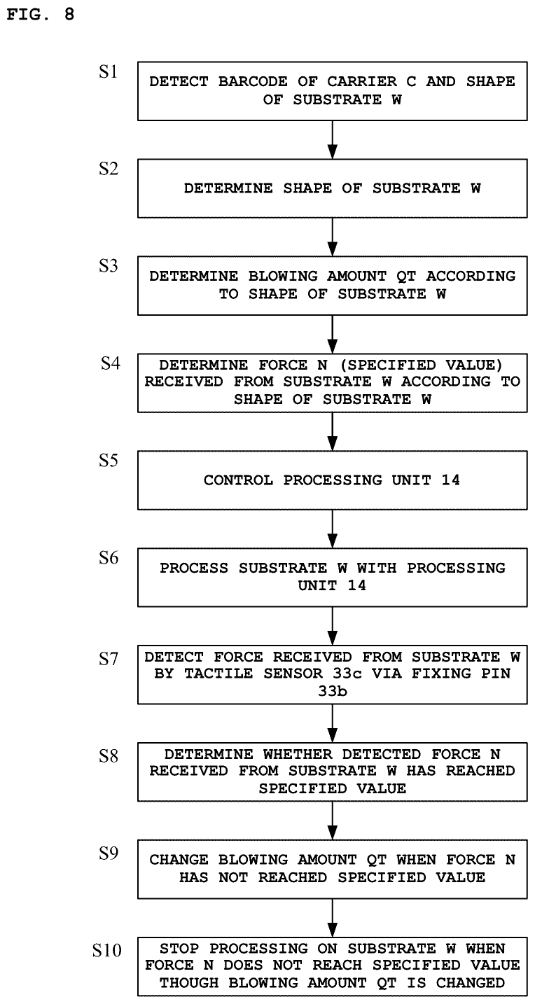

FIG. 8 is a flowchart illustrating a procedure of control of the controller 18 and operation of the processing unit 14.

### Step S1

The barcode reader 4 reads the barcode attached to the carrier C. The barcode reader 4 outputs a detection result of the barcode reader 4 to the controller 18. The shape detector 13 detects the shape of the substrate W placed on the placement part 12. The shape detector 63 detects the shape of the substrate W supported by the fixing pin 33. The shape detectors 13 and 63 output detection results of the shape detectors 13 and 63 to the controller 18.

### Step S2

The controller 18 acquires the detection results of the barcode reader 4 and the shape detectors 13 and 63. The controller 18 determines the shape of the substrate W supported by the fixing pins 33 based on the detection results of the barcode reader 4 and the shape detectors 13 and 63. Specifically, the controller 18 determines that the substrate W supported by the fixing pins 33 is the normal substrate WN.

The controller 18 manages the position of the substrate W and the shape of the substrate W in association with each other even after the substrate W is taken out from the carrier C. Specifically, the controller 18 manages the shape of the substrate W conveyed by the conveyance mechanisms 5 and 15 at each time, the shape of the substrate W placed on the placement part 12 at each time, and the shape of the substrate W supported by the fixing pins 33 at each time.

### Step S3

The controller 18 determines in advance the flow rate of the gas blown out from the gas outlet 34 according to the shape of the substrate W supported by the fixing pin 33. Hereinafter, the flow rate of the gas blown out from the gas outlet 34 is abbreviated as “blowing amount QT”. For example, the controller 18 stores in advance a correspondence relationship between the shape of the substrate W and the blowing amount QT. The controller 18 determines the blowing amount QT according to the shape of the substrate W determined in Step S2 from the correspondence relationship. The controller 18 changes the blowing amount QT according to the shape of the substrate W supported by the fixing pin 33.

Specifically, the controller 18 changes the blowing amount QT according to the shape of the substrate W supported by the fixing pin 33.

For example, when the substrate W is the normal substrate WN, the controller 18 determines the blowing amount QT according to the shape of the normal substrate WN (the thickness TN1 of the main portion 23). When the substrate W is the special substrate WS, the controller 18 determines the blowing amount QT according to the shape of the special substrate WS (the thickness TS1 of the main portion 23).

For example, when the shape of the substrate W supported by the fixing pins 33 is the normal substrate WN, the controller 18 determines the blowing amount QT as a first blowing amount Q1a. When the shape of the substrate W supported by the fixing pins 33 is the special substrate WS, the controller 18 determines the blowing amount QT as a second blowing amount Q2a smaller than the first blowing amount Q1a.

### Step S4

The controller 18 determines in advance the force N (specified value) received from the substrate W according to the shape of the substrate W. Hereinafter, the value of the force N received from the substrate W necessary for rotating the substrate W at a predetermined speed (hereinafter, referred to as a specified rotation speed) is referred to as a “rotation specified value”. The value of the force N received from the substrate W necessary for performing processing of supplying the treating fluid to the substrate W rotated at the specified rotation speed is referred to as a “processing specified value”. When the rotation specified value and the processing specified value are collectively referred to, they are simply referred to as “specified values”. For example, the controller 18 stores in advance a correspondence relationship between the shape of the substrate W and the specified values. The controller 18 determines the specified values according to the shape of the substrate W determined in Step S2 from the correspondence relationship.

The controller 18 may determine the specified values according to the shape of the substrate W as follows. For example, the controller 18 stores in advance the correspondence relationship between the blowing amount QT and the specified value. The controller 18 determines the specified values according to the blowing amount QT determined according to the shape of the substrate W determined in Step S3 from the correspondence relationship. The controller 18 stores in advance the correspondence relationship between the shape of the substrate W, the blowing amount Qt, and the specified values.

The specified value is a value of the force N received from the substrate W detected by the tactile sensor 33c when the gas outlet 34 blows out the gas having the blowing amount QT to the lower surface 26 of the normal substrate WN or the special substrate WS in advance.

The special substrate WS has lower rigidity than the normal substrate WN. The blowing amount QT of the gas blown out to the lower surface 26 of the special substrate WS is smaller than that to the normal substrate WN in consideration of low rigidity of the special substrate WS. Thus, the specified value of the special substrate WS is smaller than the specified value of the normal substrate WN.

For example, when the shape of the substrate W supported by the fixing pin 33 is the normal substrate WN, the controller 18 determines the rotation specified value as a first rotation specified value N1a and determines the processing specified value as a first processing specified value N1a+α in response to the determination of the blowing amount QT as the first blowing amount Q1a. When the shape of the substrate W supported by the fixing pin 33 is the special substrate WS, the controller 18 determines the rotation specified value as a second rotation specified value N2a smaller than the first rotation specified value N1a and determines the processing specified value as a second processing specified value N2a+α smaller than the first processing specified value N1a+α in response to the determination of the blowing amount QT as the second blowing amount Q2a smaller than the first blowing amount Q1a.

### Step S5

The controller 18 controls the processing unit 14. The controller 18 controls the blowing adjuster 40 based on the determined blowing amount QT. For example, when the shape of the substrate W is the shape of the normal substrate WN, the blowing amount QT targeted by the blowing adjuster 40 is the first blowing amount Q1a corresponding to the shape of the normal substrate WN. For example, when the shape of the substrate W is the shape of the special substrate WS, the blowing amount QT targeted by the blowing adjuster 40 is the second blowing amount Q2a corresponding to the shape of the special substrate WS.

### Step S6

Under the control of the controller 18, the processing unit 14 performs processing on the substrate W. Specifically, the blowing adjuster 40 supplies gas to the gas outlet 34 at the determined blowing amount QT. For example, when the shape of the substrate W is the shape of the normal substrate WN, the gas outlet 34 blows gas to the lower surface 26 of the normal substrate WN at the first blowing amount Q1a corresponding to the shape of the normal substrate WN. For example, when the shape of the substrate W is the shape of the special substrate WS, the gas outlet 34 blows gas to the lower surface 26 of the special substrate WS at the second blowing amount Q2a corresponding to the shape of the special substrate WS.

The gas blown out from the outlet 34 is supplied between the upper surface 32a of the plate 32 and the lower surface 26 of the substrate W supported by the fixing pin 33. The gas flows outward along the lower surface 26 of the substrate W. The gas flows out from the space between the upper surface 32a of the plate 32 and the lower surface of the substrate W supported by the fixing pin 33. The gas flows out to a space outside the peripheral edge 22 of the substrate W. Such a gas flow causes a suction force corresponding to the first rotation specified value N1a to act on the substrate W. The substrate holder 31 holds the substrate W on the fixing pin 33 using the suction force. When the gas reaches the first blowing amount Q1a, the suction force corresponding to the first processing specified value N1a+α acts on the substrate W.

When the suction force corresponding to the first processing specified value N1a+α acts on the substrate W, the rotation driver 45 rotates the substrate holder 31. This causes the substrate W supported by the fixing pins 33 to rotate. The substrate W supported by the fixing pins 33 rotates integrally with the plate 32.

In a state where the substrate W is sucked by the fixing pin 33 with a suction force corresponding to the first processing specified value N1a+α and the plate 32 maintains a specified rotation speed, the controller 18 causes the flow rate adjuster 57 to supply a necessary treating fluid to the nozzle 52. The nozzle 52 discharges the treating fluid. This causes the treating fluid supply part 51 to supply the treating fluid to the upper surface 27 of the substrate W. The treating fluid scatters outward from the substrate W supported by the fixing pin 33. The guard 61 collects the scattered treating fluid.

Even though the gas of the blowing amount QT appropriately preset according to the shape of the substrate W is supplied to the lower surface 26 of the substrate W like this, the suction force corresponding to the required rotation specified value or processing specified value does not act on the substrate W in some cases.

For example, depending on the type of the film formed on the substrate W, the frictional force between the substrate W and the fixing pin 33 may decrease. The type of the film formed on the substrate W is, for example, an oxide film. The oxide film formed on the substrate W is in contact with the fixing pin 33. In such a case, even though the suction force acts on the substrate W supported by the fixing pin 33, the substrate W easily moves in the horizontal direction with respect to the fixing pin 33. The suction force acting on the substrate W supported by the fixing pin 33 decreases as the substrate W moves more easily.

For example, the frictional force generated between the fixing pin 33 and the substrate W may be reduced by the treating fluid supplied by the treating fluid supply part 51. The treating fluid may flow from the main portion 23 of the substrate W supported by the fixing pin 33 to the peripheral edge 22. The treating fluid that has flown around the peripheral edge 22 of the substrate W may enter between the fixing pin 33 and the substrate W. As a result, the frictional force between the fixing pin 33 and the substrate W may decrease. As a result, the suction force acting on the substrate W supported by the fixing pin 33 decreases.

In this manner, when the frictional force between the substrate W and the fixing pin 33 decreases during the processing of the substrate W, the force N received by the fixing pin 33 from the substrate W does not reach the suction force corresponding to the required rotation specified value or the processing specified value when the suction force according to Bernoulli's principle acts on the substrate W supported by the fixing pin 33. The controller 18 detects a decrease in frictional force between the substrate W and the fixing pin 33 by detecting the force N that the tactile sensor 33c receives from the substrate W via the fixing pin 33b. Then, the controller 18 controls the processing unit 14, for example, the blowing amount QT is adjusted based on the detection result. This makes it possible to prevent the substrate W from being continuously processed without the suction force reaching a suction force corresponding to the required rotation specified value or the processing specified value. The processing of the substrate W includes processing of rotating the substrate W until reaching a specified rotation speed and processing of supplying a treating fluid to the substrate W rotating at the specified rotation speed. Hereinafter, a specific description will be given.

### Step S7

The controller 18 detects the force N received by the tactile sensor 33c from the substrate W via the fixing pin 33b. The tactile sensor 33c detects a pressing force with which the substrate W presses the fixing pin 33 when a suction force according to Bernoulli's principle acts on the substrate W supported by the fixing pin 33. This pressing force is the force N received from the substrate W. The tactile sensor 33c transmits information on the detected pressing force to the controller 18. The controller 18 acquires information on the pressing force transmitted from the tactile sensor 33c.

### Step S8

The controller 18 determines whether the detected force N received from the substrate W has reached a specified value.

For example, when the shape of the substrate W supported by the fixing pin 33 is the shape of the normal substrate WN, the controller 18 determines whether the detected force N received from the substrate W has reached the first rotation specified value N1a in response to determining the rotation specified value as the first rotation specified value N1a. The controller 18 determines whether the detected force N received from the substrate W has reached the first processing specified value N1a+α in response to determining the processing specified value as the first processing specified value N1a+α. When the shape of the substrate W supported by the fixing pin 33 is the shape of the special substrate WS, the controller 18 determines whether the detected force N received from the substrate W has reached the second rotation specified value N2a in response to determining the rotation specified value as the second rotation specified value N2a. The controller 18 determines whether the detected force N received from the substrate W has reached the second processing specified value N2a+α in response to determining the processing specified value as the second processing specified value N2a+α.

### Step S9

The controller 18 changes the blowing amount Qt when the detected force N received from the substrate W has not reached the specified value. In this case, it is presumed that an event has occurred in which the frictional force between the substrate W and the fixing pin 33 described above has decreased.

For example, when the shape of the substrate W supported by the fixing pins 33 is the shape of the normal substrate WN, the controller 18 changes the blowing amount QT to a blowing amount QT larger than the current blowing amount QT when the detected force N received from the substrate W has not reached the first rotation specified value N1a or the first processing specified value Na+α.

Specifically, for example, the blowing amount QT is changed to a third blowing amount Q3a larger than the first blowing amount Q1a. The third blowing amount Q3a may be a value that increases stepwise. The third blowing amount Q3a is a value included in an appropriate range as the blowing amount QT with respect to the normal substrate WN.

For example, when the shape of the substrate W supported by the fixing pins 33 is the shape of the special substrate WS, the controller 18 changes the blowing amount QT to a blowing amount QT larger than the current blowing amount QT when the detected force N received from the substrate W has not reached the second rotation specified value N2a or the second processing specified value N2a+α.

Specifically, for example, the blowing amount QT is changed to a fourth blowing amount Q4a larger than the second blowing amount Q2a. The fourth blowing amount Q4a may be a value that increases stepwise. The fourth blowing amount Q4a is a value included in an appropriate range as the blowing amount QT with respect to the special substrate WS.

The controller 18 repeats the processing of Step 9 for a predetermined period or a predetermined number of times. The controller 18 continues the processing on the substrate W when the detected force N received from the substrate W has reached the specified value. When the processing on the substrate W is completed, the controller 18 stops blowing out the gas and the rotation of the plate 32.

### Step S10

When the detected force N formed from the substrate W does not reach the specified value even though the blowing amount QT is changed for a predetermined period or a predetermined number of times, the controller 18 stops the processing on the substrate W with the processing unit 14. This makes it possible to prevent an event that may occur based on a decrease in frictional force between the substrate W and the fixing pin 33.

<Graph (1) Illustrating Relationship Between Force N Received from Substrate and Elapsed Time According to First Embodiment>

A relationship between the force N received from the substrate and the elapsed time according to the first embodiment will be described with reference to the drawings. The relationship between the adjusted blowing amount and the elapsed time will also be described. In particular, in Graph (1), a case where the force N received from the substrate W detected before treating fluid supply processing does not reach the specified value necessary for the treating fluid supply processing for the substrate W will be described.

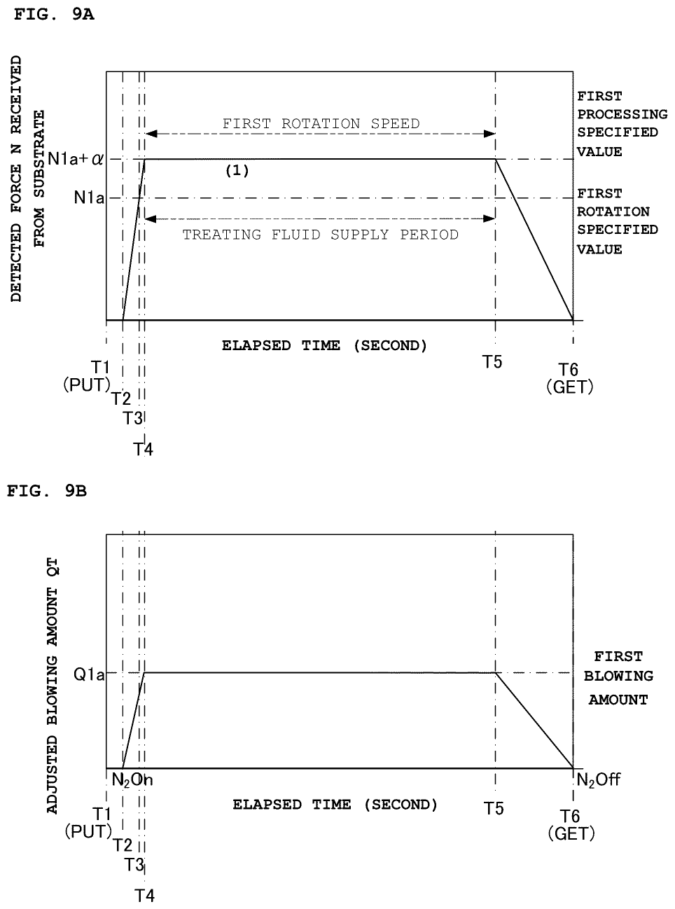

FIG. 9A is a graph (Graph (1)) illustrating a relationship between the force N received from the substrate and the elapsed time according to the first embodiment, and FIG. 9B is a graph illustrating a relationship between the adjusted blowing amount QT and the elapsed time according to the first embodiment. In the graph illustrated in FIG. 9A, the substrate W to be processed is the normal substrate WN. In the graph illustrated in FIG. 9A, one type of treating fluid is supplied. The timing shown in the graphs is common to the graphs of 9A and 9B.

The timing T1 is a timing at which the normal substrate WN is placed on the fixing pin 33. The timing T2 is a timing at which the supply of nitrogen (N₂) gas starts. The timing at which the normal substrate WN is placed on the fixing pin 33 and the timing at which the supply of the nitrogen (N₂) gas starts may be switched.

Further, the timing T2 is a timing at which the force N received from the normal substrate WN by the tactile sensor 33c illustrated in FIG. 9A starts to be detected.

The nitrogen gas is supplied by the blowing adjuster 40 until reaching the first blowing amount Q1a. The nitrogen gas reaches the first blowing amount Q1a at the timing T4.

At the timing T3, the detected force N received from the normal substrate WN reaches the first rotation specified value N1a. The first rotation specified value N1a is a value of the force N received from the normal substrate WN necessary for preventing the normal substrate WN from being detached from the fixing pin 33 in a state where the plate 32 is rotating. That is, the first rotation specified value N1a is a target value of the force N received from the normal substrate WN necessary for rotating the normal substrate WN. When the suction force corresponding to the first rotation specified value N1a is applied to the normal substrate WN, the normal substrate WN is not detached from the fixing pin 33 unless the frictional force between the fixing pin 33 and the normal substrate WN described later decreases. The period from the timing T2 to the timing T3 is a feedback control period in which the controller 18 causes the detected force N received from the normal substrate WN to reach the first rotation specified value N1a.

At the timing T3, the controller 18 causes the rotation driver 45 to start the rotation of the plate 32 by obtaining the suction force corresponding to the first rotation specified value N1a. The plate 32 reaches a first rotation speed that is a specified rotation speed at the timing T4, for example. From the timing T3 to the timing T5, the normal substrate WN rotates at the first rotation speed.

At the timing T4, the detected force N received from the normal substrate WN reaches the first processing specified value N1a+α. The first processing specified value N1a+α is a force required when the treating fluid supply part 51 supplies the treating fluid to the upper surface 27 of the normal substrate WN rotating at the first rotation speed.

The controller 18 causes the treating fluid supply part 51 to supply the treating fluid to the upper surface 27 of the normal substrate WN, for example, at the timing T4 when the detected force N received from the normal substrate WN reaches the first processing specified value N1a+α. The value of “+α” varies based on the type of the treating fluid and the flow rate of the treating fluid.

The period from the timing T3 to the timing T4 is a feedback control period for making the detected force N received from the normal substrate WN reach from the first rotation specified value N1a to the first processing specified value N1a+α. The period from the timing T4 to the timing T5 is a feedback control period for maintaining the detected force N received from the normal substrate WN to the first processing specified value N1a+α.

In this example, since nitrogen gas is supplied until reaching the first blowing amount Q1a, the detected force N received from the normal substrate WN exceeds the first rotation specified value N1a at the timing T3, and then continues to increase until reaching the first processing specified value N1a+α at the timing T4. The first processing specified value N1a+α is set as a value in a range in which the normal substrate WN can be normally processed. Thus, even though the detected force N received from the normal substrate WN has increased from the first rotation specified value N1a to the first processing specified value N1a+α, no problem occurs in the normal substrate WN.

In addition, by increasing the specified value from the first rotation specified value N1a by a, the suction force is prevented from becoming lower than the first rotation specified value N1a because of the change in the airflow of the nitrogen gas N2 generated when the treating fluid is supplied to the upper surface 27 of the normal substrate WN while the first rotation specified value N1a is maintained. This causes the normal substrate WN to rotate in a state where a necessary suction force is applied during supply of the treating fluid.

The period from the timing T4 to the timing T5 is a period in which the treating fluid is supplied to the normal substrate WN. The controller 18 determines whether the detected force N received from the normal substrate WN falls below the first processing specified value N1a+α in a treating fluid supply period, and determines whether the detected force N received from the normal substrate WN has the first rotation specified value N1a or a larger value when the detected force N falls below the first processing specified value N1a+α. In this example, since the detected force N received from the normal substrate WN maintains the first processing specified value N1a+α, the supply of the treating fluid is continued as it is. The treating fluid is supplied to, for example, the back surface of the substrate W (the upper surface 27 of the substrate W) by the treating fluid supply part 51.

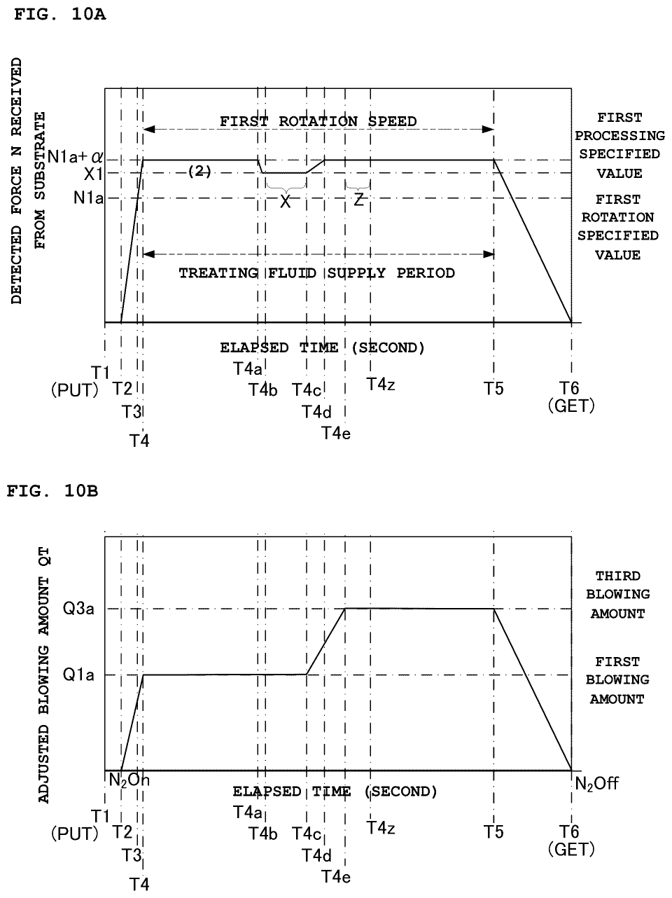

When the detected force N received from the normal substrate WN has fallen below the first processing specified value N1a+α, but the detected force N received from the normal substrate WN has not fallen below the first rotation specified value N1a, the controller 18 adjusts the blowing amount QT such that the detected force N received from the normal substrate WN reaches the first processing specified value N1a+α again. This point will be described later with reference to FIGS. 10A and 10B.

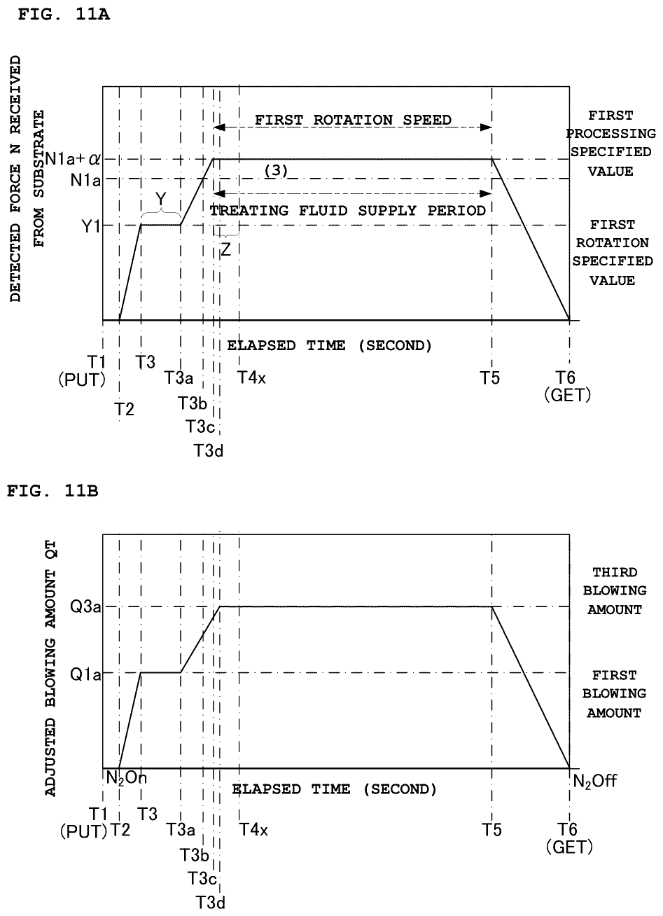

When the detected force N received from the normal substrate WN has fallen below the first processing specified value N1a+α, and the detected force N received from the normal substrate WN has fallen below the first rotation specified value N1a, the normal substrate WN may be detached from the fixing pin 33, and thus the controller 18 stops the processing. This point will be described later with reference to FIGS. 11A and 11B.

The processing from the timing T5 to the timing T6 is processing for finishing the substrate processing on the normal substrate WN. The nitrogen gas is gradually reduced from the first blowing amount Q1a by the blowing adjuster 40 and becomes 0 at the timing T6. The rotation of the plate 32 is gradually decelerated by the rotation driver 45 and becomes 0 at the timing T6. After the timing T6, the normal substrate WN after the substrate processing is taken out from the fixing pin 33.

<Graph (2) Illustrating Relationship Between Force N Received from Substrate and Elapsed Time According to First Embodiment>

A relationship between the force N received from the substrate and the elapsed time according to the first embodiment different from FIGS. 9A and 9B described above will be described. The relationship between the adjusted blowing amount and the elapsed time will also be described. In particular, in Graph (2), a case where the force N received from the substrate W detected during the treating fluid supply processing falls below the first processing specified value N1a+α necessary for the treating fluid supply processing for the substrate W but does not fall below the first rotation specified value N1a will be described.

FIG. 10A is a graph (Graph (2)) illustrating a relationship between the force N received from the substrate and the elapsed time according to the first embodiment, and FIG. 10B is a graph illustrating a relationship between the adjusted blowing amount QT and the elapsed time according to the first embodiment. The substrate W to be processed is the normal substrate WN. The timing shown in the graphs is common to the graphs of 10A and 10B.

The timings T1, T2, T3, and T4 illustrated in Graph (2) are the same as those in Graph (1) described with reference to FIGS. 9A and 9B.

From the timing T4 to the timing T5, the detected force N received from the normal substrate WN is supposed to maintain the first processing specified value N1a+α necessary for the treating fluid supply processing in a normal situation. However, as described above, the frictional force generated between the fixing pin 33 and the substrate W may be reduced by the treating fluid supplied by the treating fluid supply part 51, for example. In such a case, for example, at the timing T4a to the timing T4b, the detected force N received from the normal substrate WN decreases to the force X1 that is, for example, lower than the first processing specified value N1a+α and equal to or larger than the first rotation specified value N1a. Thus, in the period X from the timing T4b to the timing T4c, to determine whether the force X1 is erroneously detected, the controller 18 determines whether the detected force N received from the normal substrate WN returns to the first processing specified value N1a+α while maintaining the first blowing amount Q1a.

When the detected force N received from the normal substrate WN has returned to the first processing specified value N1a+α in the period X, the controller 18 determines that the force X1 is erroneously detected, and continues the treating fluid supply processing to the normal substrate WN as it is. When the detected force N received from the normal substrate WN does not return to the first processing specified value N1a+α in a state where the first blowing amount Q1a is maintained in the period X, the controller 18 determines that the detection of the force X1 is correct at the timing T4c, and changes the blowing amount QT from the first blowing amount Q1a to the third blowing amount Q3a. The controller 18 determines whether the detected force N received from the normal substrate WN returns to the first processing specified value N1a+α in the process in which the blowing amount QT increases from the first blowing amount Q1a to the third blowing amount Q3a. The blowing amount QT may be changed to the third blowing amount Q3a as soon as the detected force N received from the normal substrate WN has decreased to the force X1 without providing the period X.

At the timing T4d, the detected force N received from the normal substrate WN returns to the first processing specified value N1a+α. Thereafter, at the timing T4e, the blowing amount QT reaches the third blowing amount Q3a. In the graph illustrated in (2), the force N received from the normal substrate WN corresponding to the third blowing amount Q3a should be larger than the first processing specified value N1a+α, but is converged at the first processing specified value N1a+α by the feedback control. The controller 18 maintains the detected force N received from the normal substrate WN at N1a+α by gradually making the blowing amount QT of the nitrogen gas constant at the timing when the detected force N received from the normal substrate WN has reached the first processing specified value N1a+α. This makes it possible to eliminate waste of supply of the nitrogen gas. The controller 18 may increase the force N received from the normal board WN to a value corresponding to the third blowing amount Q3a as long as the force N received from the normal board WN corresponding to the third blowing amount Q3a is a value with which the normal substrate WN can be processed normally.

From the timing T4e to the timing T5, the controller 18 continues the treating fluid supply processing for the normal substrate WN as it is in a state where the detected force N received from the normal substrate WN is maintained at the first processing specified value N1a+α.

The processing from the timing T5 to the timing T6 is processing of finishing the substrate processing on the normal substrate WN as in Graph (1).

In the period Z from the timing T4e to the timing T4z, the controller 18 determines whether the detected force N received from the normal substrate WN returns to the first processing specified value N1a+α while maintaining the third blowing amount Q3a. When the force N received from the normal substrate WN detected in the period Z has returned to the first processing specified value N1a+α, the treating fluid supply processing to the normal substrate WN continues as it is, as described above. When the force N received from the normal substrate WN detected in the period Z does not return to the first processing specified value N1a+α, the controller 18 stops the rotation of the plate 32 at the end of the period Z. After stopping the rotation of the plate 32, the controller 18 stops the supply of the nitrogen gas. This makes it possible to prevent the treating fluid supply processing from continuing in a state where the frictional force between the substrate W and the fixing pin 33 is reduced, that is, in a state where a necessary suction force is not applied to the normal substrate WN.

In the graph shown in (2), for example, also when the detected force N received from the normal substrate WN has decreased to a value lower than the first rotation specified value N1a from the timing T4a to the timing T4b, the controller 18 stops the rotation of the plate 32 and stops the supply of the nitrogen gas. The value in which the force N received from the normal substrate WN is lower than the first rotation specified value N1a includes 0 and a value as close as possible to 0. This can prevent the treating fluid supply processing from continuing in a state where the frictional force between the substrate W and the fixing pin 33 is significantly reduced. The above-described period X may be provided in this processing. It is possible to determine whether the decrease in the detected force N received from the normal substrate WN is an erroneous detection.

<Graph (3) Illustrating Relationship Between Force N Received from Substrate and Elapsed Time According to First Embodiment>

A relationship between the force N received from the substrate and the elapsed time according to the first embodiment different from FIGS. 9A, 9B, 10A and 10B described above will be described. The relationship between the adjusted blowing amount and the elapsed time will also be described. In particular, in Graph (3), a case where the force N received from the substrate W detected before substrate rotation does not reach the rotation specified value necessary for the treating fluid supply processing for the substrate W will be described.

FIG. 11A is a graph (Graph (3)) illustrating a relationship between the force N received from the substrate and the elapsed time according to the first embodiment different from FIGS. 9A and 10A, and FIG. 11B is a graph illustrating a relationship between the adjusted blowing amount QT and the elapsed time according to the first embodiment different from FIGS. 9B and 10B. The substrate W to be processed is the normal substrate WN. The timing shown in the graphs is common to the graphs of 11A and 11B.

The timings T1 and T2 are the same as those in Graphs (1) and (2) described with reference to FIGS. 9A, 9B, 10A and 10B.

At the timing T3, the detected force N received from the normal substrate WN is supposed to reach the first rotation specified value N1a in a normal situation. However, as described above, for example, there is a case where the clearance between the fixing pin 33 and the lower surface 26 of the substrate W is not sufficient, or a case where the frictional force generated between the fixing pin 33 and the normal substrate W is reduced. In such a case, the detected force N received from the normal substrate WN may be Y1, which is lower than the first rotation specified value N1a. Y1 includes a value at which the detected force N received from the normal substrate WN is 0 or as close as possible to 0. In the period Y from the timing T3 to the timing T3a, to determine whether Y1 is erroneously detected, the controller 18 determines whether the detected force N received from the normal substrate WN reaches to the first rotation specified value N1a while maintaining the first blowing amount Q1a.

When the detected force N received from the normal substrate WN has reached the first rotation specified value N1a in the period Y, the controller 18 starts the rotation of the plate 32. When the detected force N received from the normal board WN in the period Y is Y1, the controller 18 changes the blowing amount QT from the first blowing amount Q1a to the third blowing amount Q3a at the timing T3a.

The controller 18 determines whether the detected force N received from the normal substrate WN reaches the first rotation specified value N1a and the first processing specified value N1a+α when the time period when the blowing amount QT reaches from the first blowing amount Q1a to the third blowing amount Q3a. At the timing T3b, the detected force N received from the normal substrate WN reaches the first rotation specified value N1a. At the timing T3c after the force N reaches the first rotation specified value N1a, the detected force N received from the normal substrate WN reaches the first processing specified value N1a+α.

At the timing T3d, the blowing amount QT reaches the third blowing amount Q3a. In the graph illustrated in (3), the force N received from the normal substrate WN corresponding to the third blowing amount Q3a should be larger than the first processing specified value N1a+α, but is converged at the first processing specified value N1a+α by the feedback control as in (2). This makes it possible to eliminate waste of supply of the nitrogen gas. The controller 18 may increase the force N received from the normal board WN to a value corresponding to the third blowing amount Q3a as in (2).

From the timing T3c to the timing T5, the controller 18 executes the treating fluid supply processing on the normal substrate WN in a state where the detected force N received from the normal substrate WN is maintained at the first processing specified value N1a+α.

The processing from the timing T5 to the timing T6 is processing of finishing the substrate processing on the normal substrate WN as in Graph (1).

In the period Z from the timing T3d to the timing T4x, the controller 18 determines whether the detected force N received from the normal substrate WN reaches the first rotation specified value N1a and the first processing specified value N1a+α while maintaining the third blowing amount Q3a. When the detected force N received from the normal substrate WN detected in the period Z has reached the first processing specified value N1a+α, the rotation of the plate 32 starts. When the force N received from the normal substrate WN detected in the period Z has reached the first processing specified value N1a+α, the treating fluid supply processing on the normal substrate WN starts.

When the force N received from the normal substrate WN detected in the period Z does not reach the first rotation specified value N1a, the controller 18 stops the rotation of the plate 32 at the end of the period Z. This makes it possible to prevent the plate 32 from starting to rotate in a state where the frictional force between the substrate W and the fixing pin 33 is reduced, that is, in a state where a necessary suction force corresponding to the first rotation specified value N1a is not applied to the normal substrate WN.

Also when the force N received from the normal substrate WN detected in the period Z does not reach the first processing specified value N1a+α, the controller 18 stops the rotation of the plate 32 at the end of the period Z. This makes it possible to prevent the treating fluid supply processing on the normal substrate WN from starting in a state where the frictional force between the substrate W and the fixing pin 33 is reduced, that is, in a state where a suction force corresponding to the first processing specified value N1a+α is not applied to the normal substrate WN.

In the graph illustrated in (3), when the detected force N received from the normal substrate WN is 0 or a value as close as possible to 0 from the detection start time point, the controller 18 may stop the supply of the nitrogen gas. This can prevent processing of supplying gas to the substrate W from starting when the substrate W is not correctly placed on the fixing pin 33 from the beginning.

### Effect of First Embodiment

The substrate processing apparatus 1 includes the processing unit 14 that processes a substrate, and a controller 18 that controls the processing unit 14, in which the processing unit 14 includes the plate 32 having the upper surface 32a, the rotation driver 45 that rotates the plate 32, the fixing pin 33 (33a, 33b) that protrudes upward from the upper surface 32a of the plate 32, is in contact with at least one of the lower surface 26 of the substrate W and the peripheral edge 22 of the substrate W, and supports the substrate W at a position higher than the upper surface 32a of the plate 32, the gas outlet 34 that is formed on the upper surface 32a of the plate 32 and blows gas upward, the blowing adjuster 40 that adjusts a flow rate of the gas blown out from the gas outlet 34, and the tactile sensor 33c that detects the force N received from the substrate W when a suction force according to Bernoulli's principle acts on the substrate W supported by the fixing pin 33b, and the controller 18 controls the processing unit 14 based on information on the force N received from the substrate W detected by the tactile sensor 33c. That is, the fixing pin 33 supports the substrate W at a position higher than the upper surface 32a of the plate 32. The gas outlet 34 blows out gas upward from the upper surface 32a of the plate 32a. The blowing adjuster 40 adjusts the flow rate of the gas blown out from the gas outlet 34. This causes a suction force according to Bernoulli's principle to act on the substrate W supported by the fixing pin 33. The tactile sensor 33c detects the force N received from the substrate W when a suction force according to Bernoulli's principle acts on the substrate W supported by the fixing pin 33. The controller 18 controls the processing unit 14 based on the information on the force N received from the substrate W detected by the tactile sensor 33c. With this configuration, when the frictional force between the substrate W and the fixing pin 33 has decreased, the force N received from the substrate W when the suction force according to the Bernoulli's principle acts on the substrate W supported by the fixing pin 33 does not sufficiently act on the substrate W. The controller 18 can detect a decrease in frictional force between the substrate W and the fixing pin 33 by detecting the force N received by the tactile sensor 33c from the substrate W. The controller 18, which changes the blowing amount Qt as an example of the control of the processing unit 14 based on the information on the detected force N received from the substrate W, can reduce the event that may occur based on the decrease in the frictional force between the substrate W and the fixing pin 33. As a result, the substrate W can be efficiently processed.

The controller 18 adjusts the blowing amount QT so that the force N received from the substrate W returns to the processing specified value when the force N received from the substrate W has decreased to a force less than the processing specified value and equal to or larger than the rotation specified value in the treating fluid supply period. This can set the force N received from the substrate W back to the force necessary for continuing the treating fluid supply processing during the processing on the substrate W with the processing unit 14 when the force N received from the substrate W has become a force less than the processing specified value and equal to or larger than the rotation specified value because of the decrease in the frictional force between the fixing pin 33 and the substrate W in the treating fluid supply period.

After the substrate W is placed on the fixing pin 33 and before the plate 32 starts to rotate, when the force N received from the substrate W does not reach the rotation specified value or the processing specified value despite the supply of the gas having the required blowing amount QT, the controller 18 adjusts the blowing amount QT so that the force N received from the substrate W becomes equal to or larger than the rotation specified value and the processing specified value. This can cause the force N received from the substrate W to have a force necessary for starting the rotation of the substrate W and starting the treating fluid supply processing on the substrate W when the force N received from the substrate W has not reached the rotation specified value or the processing specified value because of the decrease in the frictional force between the fixing pin 33 and the substrate W before the treating fluid supply period.

The specified value is a predetermined rotation specified value and a predetermined processing specified value for the processing unit 14 to start processing (rotation of the substrate W and treating fluid supply processing) on the substrate W. This allows the force N received from the substrate W to be a force necessary for the processing for rotating the substrate W and the treating fluid supply (force corresponding to the rotation specified value and the processing specified value) when the detected force N received from the substrate W does not exceed the rotation specified value and the processing specified value for the processing unit 14 to start the processing on the substrate W.

The specified value is a predetermined processing specified value for continuing the processing on the substrate W when the processing unit 14 is executing the processing on the substrate W (treating fluid supply processing). This allows the force N received from the substrate W to be a force necessary for continuing the processing on the substrate W (force corresponding to the processing specified value) when the detected force N received from the substrate W has fallen below the processing specified value necessary for continuing the processing on the substrate W when the processing unit 14 is executing the processing on the substrate W.

The specified value is a value determined in advance for each type of the shape of the substrate W. This makes it possible to determine whether the detected force N received from the substrate W has exceeded the rotation specified value or the processing specified value with the value according to the type of the shape of the substrate W. The values according to the type of the shape of the substrate W are the first rotation specified value N1a and the first processing specified value N1a+α in the case of the normal substrate WN. The values are the second rotation specified value N2a and the second processing specified value N2a+α in the case of the special substrate WS. Although not illustrated, the second rotation specified value N2a and the second processing specified value N2a+α form an approximated graph in which the value of the detected force N received from the substrate is different from those of the graphs (1) to (3) illustrated in FIGS. 9A, 9B, 10A, 10B, 11A and 11B.

### Second Embodiment

A substrate processing apparatus 1 according to a second embodiment will be described with reference to the drawings. The same components as those of the first embodiment are denoted by the same reference numerals, and a detailed description thereof will be omitted.

### <Operation Example of Processing Unit 14 of Second Embodiment>

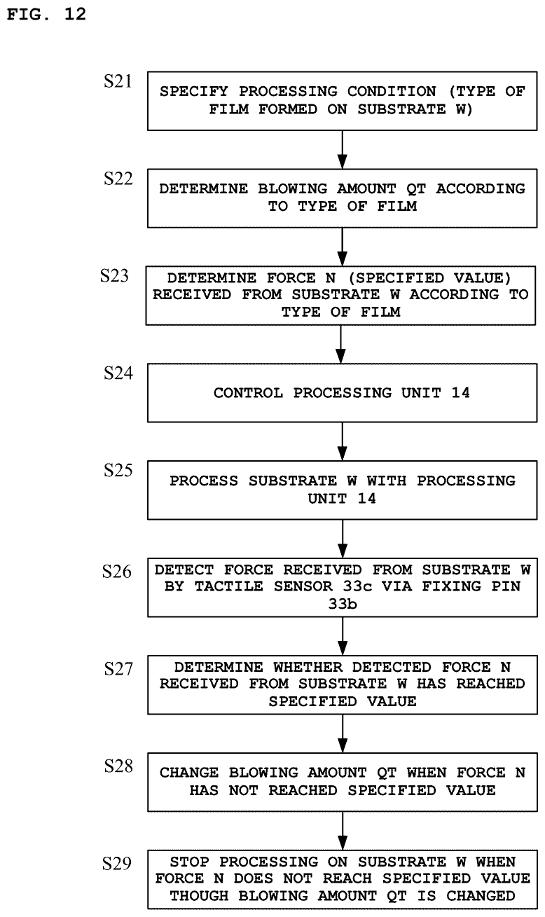

FIG. 12 is a flowchart illustrating a procedure of control of the controller 18 and operation of the processing unit 14 according to the second embodiment. In the operation example of the processing unit 14 of the second embodiment, the controller 18 changes the blowing amount QT so that the force N received from the substrate W detected by the tactile sensor 33c via the fixing pin 33b during the operation of the processing unit 14 becomes equal to or larger than a specified value determined in advance according to the shape of the film formed on the substrate W when the force N is less than the specified value. In the second embodiment, the blowing amount QT is determined in advance according to the type of the film, and a reference value corresponding to the blowing amount QT is determined in advance.

### Step S21

The controller 18 refers to the processing recipe and specifies processing conditions of the processing unit 14. An example of the processing conditions of the processing unit 14 is the type of the film formed on the substrate W. Specifically, the controller 18 specifies the type of the film that forms the lower surface 26 of the substrate W, that is, the surface of the substrate W where the substrate W comes into contact with the fixing pin 33. The type of the film is, for example, an oxide film. The type of the film is read as a detection result of the barcode reader 4. The barcode attached to the carrier C includes information on the type of the film formed on the substrate W.

### Step S22

The controller 18 determines the blowing amount QT according to the type of the film. For example, the controller 18 stores in advance a correspondence relationship between the type of the film and the blowing amount QT. The controller 18 determines the blowing amount QT according to the type of the film specified in Step S21 from the correspondence relationship.

Specifically, the controller 18 determines the blowing amount QT such that the blowing amount QT increases as the type of the film is more likely to reduce the frictional force between the substrate W and the fixing pin 33.

For example, when the type of the film is a film A that is not an oxide film, the controller 18 determines the blowing amount QT as a first blowing amount Q1b. When the type of the film is a film B that is an oxide film, the controller 18 determines the blowing amount QT as a second blowing amount Q2b larger than the first blowing amount Q1b.

### Step S23

The controller 18 determines the specified value according to the type of the film. For example, the controller 18 stores in advance a correspondence relationship between the type of the film and the specified value. The controller 18 determines the specified value according to the type of the film specified in Step S21 from the correspondence relationship.

The controller 18 may determine the specified value according to the type of the film as follows. For example, the controller 18 stores in advance the correspondence relationship between the blowing amount QT and the specified value. The controller 18 determines the specified value according to the blowing amount QT determined according to the type of the film determined in Step S22 from the correspondence relationship. The controller 18 stores in advance a correspondence relationship between the type of the film, the blowing amount QT, and the specified value.

The specified value is a value of the force N received from the substrate W detected by the tactile sensor 33c when the gas outlet 34 blows out the gas having the blowing amount QT to the lower surface 26 of the substrate W formed with the film A or the film B in advance.

The frictional force between the substrate W formed with the film B and the fixing pin 33 is lower than the frictional force between the substrate W formed with the film A and the fixing pin 33. Thus, the specified value of the substrate W formed with the film B is set to be larger than the specified value of the substrate W formed with the film A.

For example, when the film A is formed on the substrate W, the controller 18 determines the rotation specified value as a first rotation specified value N1b and determines the processing specified value as a first processing specified value N1b+α in response to the determination of the blowing amount QT as the first blowing amount Q1b. When the film B is formed on the substrate W, the controller 18 determines the rotation specified value as a second rotation specified value N2b larger than the first rotation specified value N1b and determines the processing specified value as a second processing specified value N2b+α larger than the first processing specified value N1b+α in response to the determination of the blowing amount QT as the second blowing amount Q2b larger than the first blowing amount Q1b.

### Step S24

The controller 18 controls the processing unit 14. The controller 18 controls the blowing adjuster 40 based on the determined blowing amount QT. For example, when the film formed on the substrate W is the film A, the blowing amount QT targeted by the blowing adjuster 40 is the first blowing amount Q1b corresponding to the film A. For example, when the film formed on the substrate W is the film B, the blowing amount QT targeted by the blowing adjuster 40 is the second blowing amount Q2b corresponding to the film B.

### Step S25

Under the control of the controller 18, the processing unit 14 performs processing on the substrate W. Specifically, the blowing adjuster 40 supplies gas to the gas outlet 34 at the determined blowing amount QT. For example, when the film formed on the substrate W is the film A, the gas outlet 34 blows gas to the lower surface 26 of the substrate W formed with the film A at the first blowing amount Q1b corresponding to the film A. For example, when the film formed on the substrate W is the film B, the gas outlet 34 blows gas to the lower surface 26 of the substrate W formed with the film B at the second blowing amount Q2b corresponding to the film B.

In this manner, the blowing amount QT is set according to the type of the film formed on the substrate W, that is, the frictional force between the substrate W on which the film is formed and the fixing pin 33. Thus, the suction force set according to the type of the film formed on the substrate W acts on the substrate W supported by the fixing pins 33.

For example, when the type of the film formed on the substrate W is the film A, the suction force corresponding to the first rotation specified value N1b corresponding to the first blowing amount Q1b acts on the substrate W supported by the fixing pins 33. When the gas reaches the first blowing amount Q1b, the suction force corresponding to the first processing specified value N1b+α acts on the substrate W. For example, when the type of the film formed on the substrate W is the film B, the suction force corresponding to the second rotation specified value N2b corresponding to the second blowing amount Q2b acts on the substrate W supported by the fixing pins 33. When the gas reaches the second blowing amount Q2b, the suction force corresponding to the second processing specified value N2b+α acts on the substrate W.

However, even though the blowing amount QT is set in advance according to the type of the film formed on the substrate W in this manner, as described in the first embodiment, the suction force corresponding to the required rotation specified value or processing specified value does not act on the substrate W in some cases. Thus, as in the first embodiment, the controller 18 detects a decrease in frictional force between the substrate W and the fixing pin 33 by detecting the force N that the tactile sensor 33c receives from the substrate W via the fixing pin 33b, and controls the processing unit 14, for example, adjusts the blowing amount QT based on the detection results.

### Step S26

The controller 18 detects the force N received by the tactile sensor 33c from the substrate W via the fixing pin 33b as in the first embodiment.

Step S27 The controller 18 determines whether the detected force N received from the substrate W has reached a specified value.

For example, when the type of the film formed on the substrate W is the film A, the controller 18 determines whether the detected force N received from the substrate W formed with the film A has reached the first rotation specified value N1b. The controller 18 determines whether the detected force N received from the substrate W formed with the film A has reached the first processing specified value N1b+α. When the type of the film formed on the substrate W is the film B, the controller 18 determines whether the detected force N received from the substrate W formed with the film B has reached the second rotation specified value N2b. The controller 18 determines whether the detected force N received from the substrate W formed with the film B has reached the second processing specified value N2b+α.

In this manner, the specified value for determining whether to perform the processing of changing the blowing amount QT is made different depending on whether the type of the film is the film A or the film B. This can determine whether to perform the processing of changing the blowing amount QT according to the type of the film when the frictional force between the substrate W and the fixing pin 33 is reduced.

As a result, when an event of decreasing the frictional force between the substrate W and the fixing pin 33 has occurred, it may be determined that the processing of changing the blowing amount QT is performed in the film A. However, when the same event occurs in the film B having a larger force N received from the substrate W, it may be determined that the processing of changing the blowing amount QT is not performed. Thus, even though the same event has occurred, the processing can proceed without changing the blowing amount QT in a case where the blowing amount QT does not need to be changed.

### Step S28

The controller 18 changes the blowing amount Qt when the detected force N received from the substrate W has not reached the specified value, as in the first embodiment.

For example, when the film formed on the substrate W is the film A, the controller 18 changes the blowing amount QT to a blowing amount Q3b larger than the current first blowing amount Q1b when the detected force N received from the substrate W formed with the film A has not reached the first rotation specified value N1b or the first processing specified value N1b+α.

For example, when the film formed on the substrate W is the film B, the controller 18 changes the blowing amount QT to a blowing amount Q4b larger than the current second blowing amount Q2b when the detected force N received from the substrate W formed with the film B has not reached the second rotation specified value N2b or the second processing specified value N2b+α.

### Step S29

When the detected force N formed from the substrate W does not reach the specified value even though the blowing amount QT is changed for a predetermined period or a predetermined number of times, the controller 18 stops the processing on the substrate W with the processing unit 14.

### Effect of Second Embodiment

In this manner, the substrate W is provided with a processing film, the fixing pin 33 supports the lower surface 26 on which the processing film such as the film A or the film B described above is formed, and the specified value is a value determined in advance according to the type of the processing film. This makes it possible to determine whether the detected force N received from the substrate W has exceeded the rotation specified value or the processing specified value with the value according to the type of the processing film.

### Third Embodiment

A substrate processing apparatus 1 according to a third embodiment will be described with reference to the drawings. The same components as those of the first and second embodiments are denoted by the same reference numerals, and a detailed description thereof will be omitted.

### <Operation Example of Processing Unit 14 of Third Embodiment>

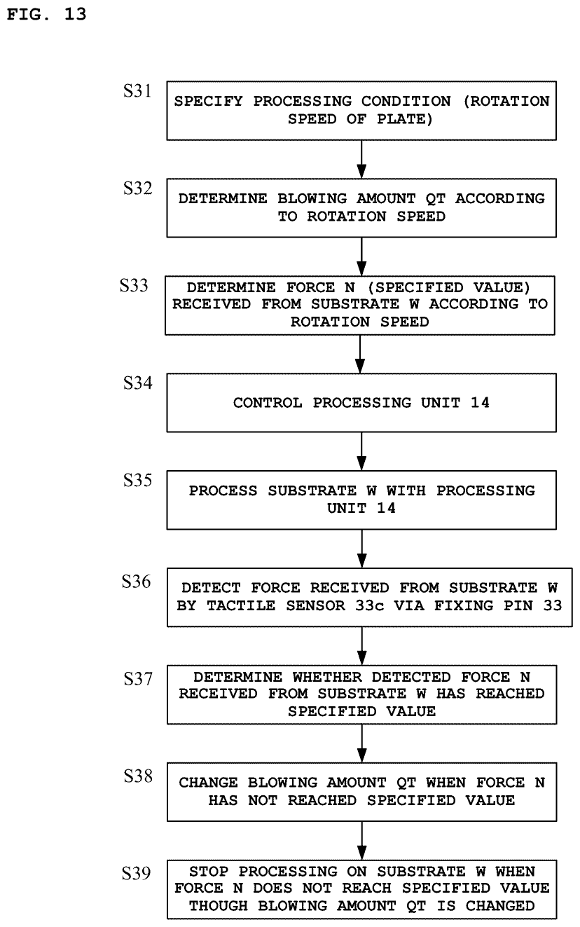

FIG. 13 is a flowchart illustrating a procedure of control of the controller 18 and operation of the processing unit 14 according to the third embodiment. In the operation example of the processing unit 14 of the third embodiment, the controller 18 changes the blowing amount QT so that the force N received from the substrate W detected by the tactile sensor 33c via the fixing pin 33b during the operation of the processing unit 14 becomes equal to or larger than a specified value determined in advance according to the rotation speed of the plate 32 when the force N is less than the specified value. In the third embodiment, the blowing amount QT is determined in advance according to the rotation speed of the plate 32, and the rotation speed of the plate 32 is determined in advance as a reference value.

### Step S31

The controller 18 refers to the processing recipe and specifies processing conditions of the processing unit 14. An example of the processing condition of the processing unit 14 is the rotation speed of the plate 32.

Specifically, the controller 18 specifies the rotation speed to be given to the rotation driver 45 for each processing recipe. The processing recipe is stored in advance in a storage medium constituting the controller 18.

### Step S32

The controller 18 determines the blowing amount QT according to the rotation speed. For example, the controller 18 stores in advance a correspondence relationship between the rotation speed and the blowing amount QT. The controller 18 determines the blowing amount QT according to the rotation speed specified in Step S31 from the correspondence relationship. The controller 18 changes the blowing amount QT according to the rotation speed.

Specifically, the controller 18 determines the blowing amount QT so that the blowing amount QT increases as the rotation speed of the plate 32 is faster in the processing recipe.

For example, when the rotation speed of the plate 32 is a first rotation speed in a first processing recipe, the controller 18 determines the blowing amount QT as a first blowing amount Q1c. When the rotation speed of the plate 32 is a second rotation speed faster than the first rotation speed in a second processing recipe, the controller 18 determines the blowing amount QT as a second blowing amount Q2c larger than the first blowing amount Q1c.

### Step S33

The controller 18 determines the specified value according to the rotation speed. For example, the controller 18 stores in advance a correspondence relationship between the rotation speed and the specified value. The controller 18 determines the specified value according to the rotation speed specified in Step S31 from the correspondence relationship.

The controller 18 may determine the specified value according to the rotation speed as follows. For example, the controller 18 stores in advance the correspondence relationship between the blowing amount QT and the specified value. The controller 18 determines the specified value according to the blowing amount QT determined according to the rotation speed determined in Step S32 from the correspondence relationship. The controller 18 stores in advance a correspondence relationship between the rotation speed, the blowing amount QT, and the specified value.

The specified value is a value of the force N received from the substrate W detected by the tactile sensor 33c when the gas outlet 34 blows out the gas having the blowing amount QT to the lower surface 26 of the substrate W rotating at a rotation speed determined in advance.

The specified value of the substrate W rotating at the second rotation speed is set to be larger than the specified value of the substrate W rotating at the first rotation speed.

For example, when the substrate W rotates at the first rotation speed, the controller 18 determines the rotation specified value as a first rotation specified value N1c and determines the processing specified value as a first processing specified value N1c+α in response to the determination of the blowing amount QT as the first blowing amount Q1c. When the substrate W rotates at the second rotation speed, the controller 18 determines the rotation specified value as a second rotation specified value N2c larger than the first rotation specified value N1c and determines the processing specified value as a second processing specified value N2c+α larger than the first processing specified value N1c+α in response to the determination of the blowing amount QT as a second blowing amount Q2c larger than the first blowing amount Q1c.

### Step S34

The controller 18 controls the processing unit 14. The controller 18 controls the blowing adjuster 40 based on the determined blowing amount QT. For example, when the rotation speed of the plate 32 is the first rotation speed in the first processing recipe, the blowing amount QT targeted by the blowing adjuster 40 is the first blowing amount Q1c corresponding to the first rotation speed. For example, when the rotation speed of the plate 32 is the second rotation speed in the second processing recipe, the blowing amount QT targeted by the blowing adjuster 40 is the second blowing amount Q2c corresponding to the second rotation speed.

### Step S35

Under the control of the controller 18, the processing unit 14 performs processing on the substrate W. Specifically, the blowing adjuster 40 supplies gas to the gas outlet 34 at the determined blowing amount QT. For example, when the rotation speed of the plate 32 in the first processing recipe is the first rotation speed, the gas outlet 34 blows gas to the lower surface 26 of the substrate W at the first blowing amount Q1c corresponding to the first rotation speed. For example, when the rotation speed of the plate 32 in the second processing recipe is the second rotation speed, the gas outlet 34 blows gas to the lower surface 26 of the substrate W at the second blowing amount Q2c corresponding to the second rotation speed.

In this manner, the blowing amount QT is set according to the type of the rotation speed of the plate 32 defined for each processing recipe. Thus, the suction force set according to the rotation speed of the plate 32 defined for each processing recipe acts on the substrate W supported by the fixing pins 33.

For example, when the rotation speed of the plate 32 in the first processing recipe is the first rotation speed, the suction force corresponding to the first rotation specified value N1c and the first processing specified value N1c+α corresponding to the first blowing amount Q1c acts on the substrate W supported by the fixing pin 33. For example, when the rotation speed of the plate 32 in the second processing recipe is the second rotation speed, the suction force corresponding to the second rotation specified value N2c and the second processing specified value N2c+α corresponding to the second blowing amount Q2c acts on the substrate W supported by the fixing pin 33.

However, even though the blowing amount QT is set in advance according to the rotation speed of the plate 32 for each processing recipe in this manner, as described in the first embodiment, the suction force corresponding to the required rotation specified value or processing specified value does not act on the substrate W in some cases. Thus, as in the first embodiment, the controller 18 detects a decrease in frictional force between the substrate W and the fixing pin 33 by detecting the force N that the tactile sensor 33c receives from the substrate W via the fixing pin 33b, and controls the processing unit 14, for example, adjusts the blowing amount QT based on the detection results.

### Step S36

The controller 18 detects the force N received by the tactile sensor 33c from the substrate W via the fixing pin 33b as in the first embodiment.

### Step S37

The controller 18 determines whether the detected force N received from the substrate W has reached a specified value.

For example, when the rotation speed of the plate 32 in the first processing recipe is the first rotation speed, the controller 18 determines whether the detected force N received from the substrate W to be processed in the first processing recipe has reached a first rotation specified value N1c. The controller 18 determines whether the detected force N received from the substrate W to be processed in the first processing recipe has reached a first processing specified value N1c+α. When the rotation speed of the plate 32 in the second processing recipe is the second rotation speed, the controller 18 determines whether the detected force N received from the substrate W to be processed in the second processing recipe has reached a second rotation specified value N2c. The controller 18 determines whether the detected force N received from the substrate W to be processed in the second processing recipe has reached a second processing specified value N2c+α.

In this manner, the specified value for determining whether to perform the processing of changing the blowing amount QT is changed depending on whether the rotation speed of the plate 32 is the first rotation speed or the second rotation speed according to the processing recipe. This can determine whether to perform the processing of changing the blowing amount QT according to the rotation speed of the plate 32 determined according to the processing recipe when the frictional force between the substrate W and the fixing pin 33 is reduced.

As a result, when an event of decreasing the frictional force between the substrate W and the fixing pin 33 has occurred, it may be determined that the processing of changing the blowing amount QT is performed at the first rotation speed in the first processing recipe. However, when the same event has occurred at the second rotation speed in the second processing recipe, it may be determined that the processing of changing the blowing amount QT is not performed. Thus, even though the same event has occurred, the processing can proceed without changing the blowing amount QT in a case where the blowing amount QT does not need to be changed.

### Step S38

The controller 18 changes the blowing amount Qt when the detected force N received from the substrate W has not reached the specified value, as in the first embodiment.

For example, when the rotation speed of the plate 32 in the first processing recipe is the first rotation speed, and the detected force N received from the substrate W to be processed in the first processing recipe has not reached the first rotation specified value N1c or the first processing specified value N1c+α, the controller 18 changes the blowing amount Qt to a blowing amount Q3c that is larger than the current first blowing amount Q1c.

For example, when the rotation speed of the plate 32 in the second processing recipe is the second rotation speed, and the detected force N received from the substrate W to be processed in the second processing recipe has not reached the second rotation specified value N2c or the second processing specified value N2c+α, the controller 18 changes the blowing amount Qt to a blowing amount Q4c that is larger than the current second blowing amount Q2c.

### Step S39

When the detected force N formed from the substrate W does not reach the specified value even though the blowing amount QT is changed for a predetermined period or a predetermined number of times, the controller 18 stops the processing on the substrate W with the processing unit 14.

### Effect of Third Embodiment

In this manner, the specified value is a value determined in advance according to the rotation speed of the plate 32. This makes it possible to determine whether the detected force N received from the substrate W has exceeded the rotation specified value or the processing specified value with the value according to the rotation speed of the plate.

### Fourth Embodiment

A substrate processing apparatus 1 according to a fourth embodiment will be described with reference to the drawings. The same components as those of the first to third embodiments are denoted by the same reference numerals, and a detailed description thereof will be omitted.

### <Operation Example of Processing Unit 14 of Fourth Embodiment>

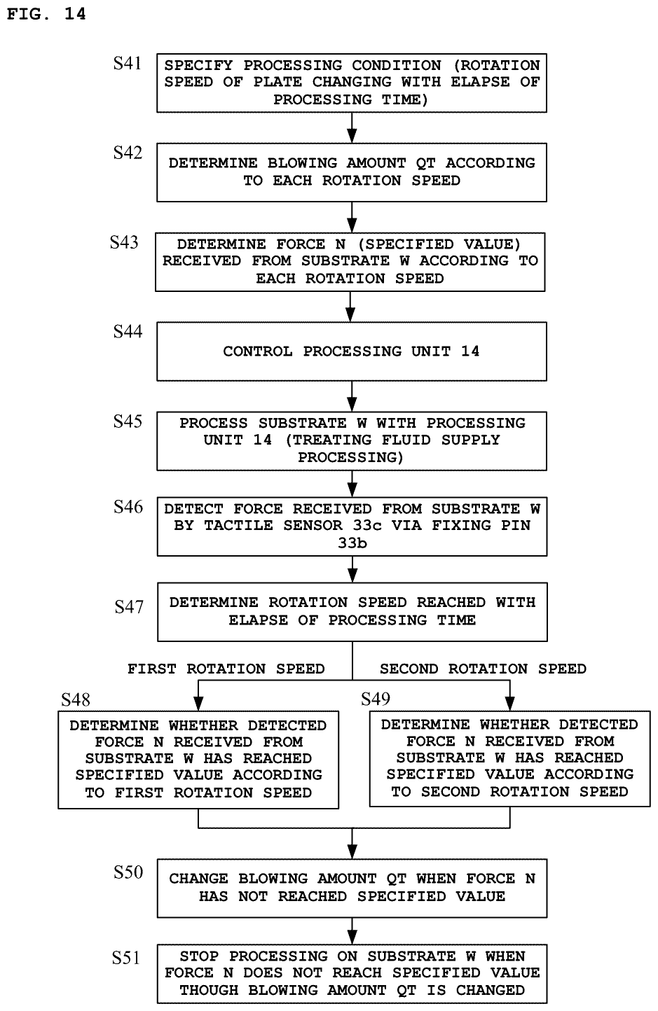

FIG. 14 is a flowchart illustrating a procedure of control of the controller 18 and operation of the processing unit 14 according to the fourth embodiment. In the operation example of the processing unit 14 of the fourth embodiment, the blowing amount QT and the specified value are determined according to the rotation speed to be reached with the lapse of the processing time in one processing recipe.

### Step S41

The controller 18 refers to the processing recipe and specifies processing conditions of the processing unit 14. In an example of the processing conditions of the processing unit 14, the processing of the substrate W is divided into first processing and second processing, and the rotation speed and the specified value are different between the first processing and the second processing. The first processing is a period in which the plate 32 on which the substrate W is placed is rotated at the first rotation speed to perform the processing. The second processing is a period in which the plate 32 on which the substrate W is placed is rotated at the second rotation speed to perform the processing. Specifically, the controller 18 specifies the rotation speed to be given to the rotation driver 45 with the lapse of the processing time. The relationship between the lapse of the processing time and the rotation speed is stored in advance as a processing recipe in the storage medium constituting the controller 18.

### Step S42

The controller 18 determines the blowing amount QT according to each rotation speed. The relationship between the lapse of the processing time, each rotation speed, and the blowing amount QT is stored in advance as a processing recipe in the storage medium constituting the controller 18.

For example, when the rotation speed of the plate 32 is the first rotation speed in the first period in a certain processing recipe, the controller 18 determines the blowing amount QT as a first blowing amount Q1d. When the rotation speed of the plate 32 is a second rotation speed faster than the first rotation speed in the second period that comes after the first period in the processing recipe, the controller 18 determines the blowing amount QT as a second blowing amount Q2d larger than the first blowing amount Q1d.

### Step S43

The controller 18 determines the specified value according to each rotation speed. The relationship between the lapse of the processing time, each rotation speed, and the specified value is stored in advance as a processing recipe in the storage medium constituting the controller 18.

The controller 18 may determine the specified value according to each rotation speed as follows. For example, the controller 18 stores in advance a correspondence relationship between the lapse of the processing time, the blowing amount QT, and the specified value. The controller 18 determines the specified value according to the blowing amount QT determined according to each rotation speed determined in Step S42 from the correspondence relationship. The controller 18 stores in advance a correspondence relationship between the lapse of the processing time, each rotation speed, the blowing amount QT, and the specified value.

The specified value is a value of the force N received from the substrate W detected by the tactile sensor 33c when the gas outlet 34 blows out gas having the blowing amount QT to the lower surface 26 of the substrate W rotating at a rotation speed that has been reached with the lapse of the processing time in advance.

The specified value of the substrate W rotating at the second rotation speed in the second period is set to be larger than the specified value of the substrate W rotating at the first rotation speed in the first period.

For example, when the substrate W rotates at the first rotation speed in the first period, the controller 18 determines the rotation specified value as a first rotation specified value N1d and determines the processing specified value as a first processing specified value N1d+α in response to the determination of the blowing amount QT as the first blowing amount Q1d. When the substrate W rotates at the second rotation speed in the second period, the controller 18 determines the rotation specified value as a second rotation specified value N2d larger than the first rotation specified value N1d and determines the processing specified value as a second processing specified value N1d+α larger than the first processing specified value N1d+α in response to the determination of the blowing amount QT as a second blowing amount Q2d larger than the first blowing amount Q1d.

### Step S44

The controller 18 controls the processing unit 14. The controller 18 controls the blowing adjuster 40 based on the determined blowing amount QT with the lapse of the processing time. For example, when the rotation speed of the plate 32 is the first rotation speed in the first period, the blowing amount QT targeted by the blowing adjuster 40 in the first period is the first blowing amount Q1d corresponding to the first rotation speed. For example, when the rotation speed of the plate 32 is the second rotation speed in the second period, the blowing amount QT targeted by the blowing adjuster 40 in the second period is the second blowing amount Q2d corresponding to the second rotation speed.

### Step S45

Under the control of the controller 18, the processing unit 14 performs processing on the substrate W. Regarding the processing on the substrate W, particularly in the fourth embodiment, the treating fluid supply processing will be described. The processing before the treating fluid is supplied is as described in the third embodiment. Specifically, the blowing adjuster 40 supplies gas to the gas outlet 34 at the determined blowing amount QT. For example, when the rotation speed of the plate 32 in the first period is the first rotation speed, the gas outlet 34 blows gas to the lower surface 26 of the substrate W at the first blowing amount Q1d corresponding to the first rotation speed from the start of the processing on the substrate W before the treating fluid supply period until the first period in the treating fluid supply period ends. For example, when the rotation speed of the plate 32 in the second period is the second rotation speed, the gas outlet 34 blows gas to the lower surface 26 of the substrate W at the second blowing amount Q2d corresponding to the second rotation speed when reaching the second period in the treating fluid supply period.

In this manner, the blowing amount QT is set according to the type of the rotation speed of the plate 32 that to be reached with the lapse of the processing time in the treating fluid supply processing. Thus, the suction force set according to the rotation speed of the plate 32 defined for the first period and the second period in the processing time acts on the substrate W supported by the fixing pins 33.

For example, when the rotation speed of the plate 32 in the first period is the first rotation speed, the suction force corresponding to the first rotation specified value N1d and the first processing specified value N1d+α corresponding to the first blowing amount Q1d acts on the substrate W supported by the fixing pin 33. For example, when the rotation speed of the plate 32 in the second period is the second rotation speed, the suction force corresponding to the second rotation specified value N2d and the second processing specified value N2d+α corresponding to the second blowing amount N2d acts on the substrate W supported by the fixing pin 33.

However, even though the blowing amount QT is set in advance according to the rotation speed of the plate 32 to be reached with the lapse of the processing time in one processing recipe, as described in the first embodiment, the suction force corresponding to the required rotation specified value or processing specified value does not act on the substrate W in some cases. Thus, as in the first embodiment, the controller 18 detects a decrease in frictional force between the substrate W and the fixing pin 33 by detecting the force N that the tactile sensor 33c receives from the substrate W via the fixing pin 33b, and controls the processing unit 14, for example, adjusts the blowing amount QT based on the detection results.

### Step S46

The controller 18 detects the force N received by the tactile sensor 33c from the substrate W via the fixing pin 33b as in the first embodiment.

### Step S47

The controller 18 determines the rotation speed of the plate 32 to be reached with the lapse of the processing time. Specifically, when the timing to perform the determination in step S47 is in a first treating fluid supply period from the start of the processing on the substrate W, it is determined that the rotation speed of the plate 32 to be reached is the first rotation speed, and the processing proceeds to step S48. When the timing to perform the determination in step S47 is in a second treating fluid supply period, it is determined that the rotation speed of the plate 32 to be reached is the second rotation speed, and the processing proceeds to step S49.

### Step S48

When the rotation speed of the plate 32 reached with the lapse of the processing time is the first rotation speed, the controller 18 determines whether the detected force N received from the substrate W has reached a specified value corresponding to the first rotation speed. Specifically, from the start of the first processing on the substrate W to the start of the treating fluid supply period, the controller 18 determines whether the detected force N received from the substrate W has reached the first rotation specified value N1d. In the first treating fluid supply period, the controller 18 determines whether the detected force N received from the substrate W has reached the first processing specified value N1d+α.

### Step S49

When the rotation speed of the plate 32 reached with the lapse of the processing time is the second rotation speed, the controller 18 determines whether the detected force N received from the substrate W has reached a specified value corresponding to the second rotation speed. Specifically, from the start of the second processing on the substrate W to the start of the second treating fluid supply period, the controller 18 determines whether the detected force N received from the substrate W has reached the second rotation specified value N2d. In the second treating fluid supply period, the controller 18 determines whether the detected force N received from the substrate W has reached the second processing specified value N2d+α.

In this manner, the specified value for determining whether to perform the processing of changing the blowing amount QT is changed depending on whether the rotation speed of the plate 32 reached with the lapse of the processing time is the first rotation speed or the second rotation speed. This can determine whether to perform the processing of changing the blowing amount QT according to the rotation speed of the plate 32 reached with the lapse of the processing time when the frictional force between the substrate W and the fixing pin 33 is reduced.

As a result, when an event of decreasing the frictional force between the substrate W and the fixing pin 33 has occurred, it may be determined that the processing of changing the blowing amount QT is performed when the rotation speed of the plate 32 to be reached with the lapse of the processing time is the first rotation speed. However, when the same event has occurred, and the rotation speed of the plate 32 to be reached with the lapse of the processing time is the second rotation speed, it may be determined that the processing of changing the blowing amount QT is not performed. Thus, even though the same event has occurred, the processing can proceed without changing the blowing amount QT in a case where the blowing amount QT does not need to be changed.

### Step S50

The controller 18 changes the blowing amount Qt when the detected force N received from the substrate W has not reached the specified value, as in the first embodiment.

For example, when the rotation speed of the plate 32 to be reached with the lapse of the processing time is the first rotation speed, and the detected force N received from the substrate W has not reached the first rotation specified value N1d or the first processing specified value N1d+α, the controller 18 changes the blowing amount Qt to a blowing amount Q3d that is larger than the current first blowing amount Q1d.

For example, when the rotation speed of the plate 32 to be reached with the lapse of the processing time is the second rotation speed, and the detected force N received from the substrate W has not reached the second rotation specified value N2d or the second processing specified value N2d+α, the controller 18 changes the blowing amount Qt to a blowing amount Q4d that is larger than the current second blowing amount Q2d.

### Step S51

When the detected force N formed from the substrate W does not reach the specified value even though the blowing amount QT is changed for a predetermined period or a predetermined number of times, the controller 18 stops the processing on the substrate W with the processing unit 14.

<Graph (4) Illustrating Relationship Between Force N Received from Substrate and Elapsed Time According to Fourth Embodiment>

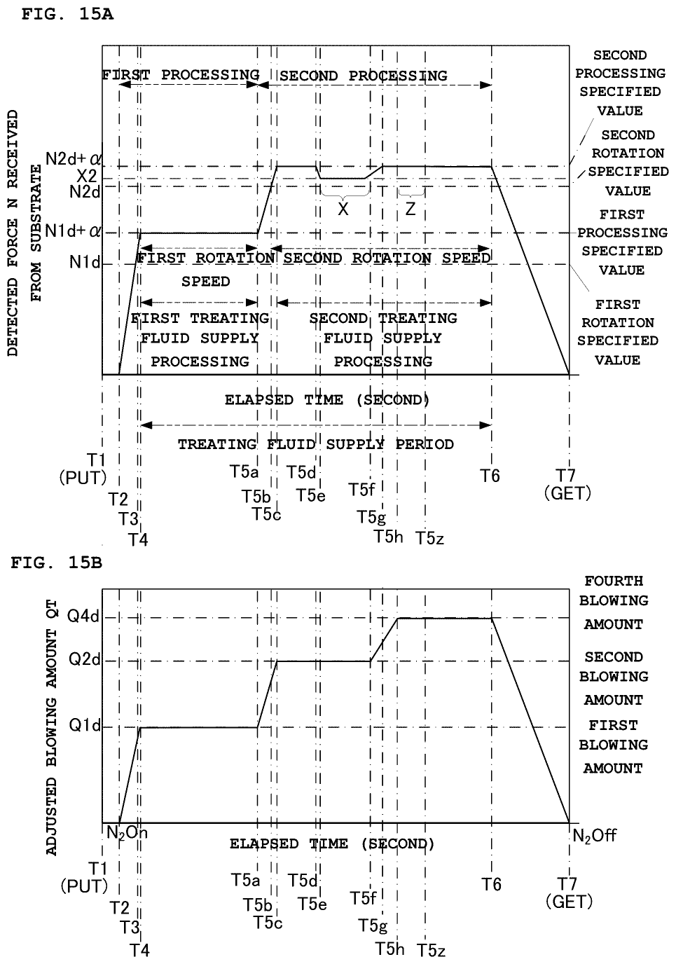

A relationship between the force N received from the substrate and the elapsed time according to a fourth embodiment will be described with reference to FIGS. 15A and 15B. The relationship between the adjusted blowing amount and the elapsed time will also be described.

FIG. 15A is a graph illustrating a relationship between the force N received from the substrate and the elapsed time according to the fourth embodiment, and FIG. 15B is a graph illustrating a relationship between the adjusted blowing amount QT and the elapsed time according to the fourth embodiment. The substrate W to be processed is the normal substrate WN. The timing shown in Graph (4) is common to the graphs of 15A and 15B.

The timings T1, T2, T3, and T4 are the same as those in Graphs (1) and (2) described with reference to FIGS. 9A, 9B, 10A and 10B in the first embodiment.

After the timing T4, the treating fluid supply processing starts. The treating fluid supply period from the timing T4 to the timing T6 is divided into a period in which the first treating fluid supply processing is performed and a period in which the second treating fluid supply processing is performed. The first treating fluid supply processing is processing for supplying the first treating fluid while rotating the plate 32 at the first rotation speed. The second treating fluid supply processing is processing for supplying the second treating fluid while rotating the plate 32 at the second rotation speed faster than the first rotation speed. The gas supply processing for rotating the substrate W at the first rotation speed to the first treating fluid supply processing correspond to the “first processing” of the present invention. The gas supply processing for rotating the substrate W at the second rotation speed to the second treating fluid supply processing correspond to the “second processing” of the present invention.

From the timing T4 to the timing T5a, the plate 32 is rotated at the first rotation speed, the nitrogen gas is supplied at the first blowing amount Q1d, and the first treating fluid is supplied. At the timing T5a, the controller 18 starts processing of supplying the nitrogen gas for rotating at the second rotation speed and performing the second treating fluid supply processing at the second blowing amount Q2d. At the timing T5b, the detected force N received from the normal substrate WN reaches the second rotation specified value N2d, and processing of increasing the rotation speed of the plate 32 from the first rotation speed to the second rotation speed starts. At the timing T5c, the blowing amount QT reaches the second blowing amount Q2d, and the detected force N received from the normal substrate WN reaches the second processing specified value N2d+α. At the timing T5c, the rotation speed of the plate 32 reaches the second rotation speed. After the timing T5c, the detected force N received from the normal substrate WN is supposed to maintain the second processing specified value N2d+α necessary for the second treating fluid supply processing in a normal situation.

However, as described above, the frictional force generated between the fixing pin 33 and the substrate W may be reduced when the rotation speed has reached the second rotation speed depending on the type of the treating fluid supplied to the substrate W, for example. In such a case, the force N received from the normal substrate WN detected between the timing T5d and the timing T5e is reduced to a force X2 which is lower than the second processing specified value N2d+α and equal to or larger than the second rotation specified value N2d. Thus, in the period X from the timing T5e to the timing T5f, to determine whether the force X2 is erroneously detected, the controller 18 determines whether the detected force N received from the normal substrate WN returns to the second processing specified value N2d+α while maintaining the second blowing amount Q2d.

When the detected force N received from the normal substrate WN has returned to the second processing specified value N2d+α in the period X, the controller 18 determines that the force X2 is erroneously detected, and the supply of the second treating fluid on the normal substrate WN is continued as it is. When the detected force N received from the normal substrate WN does not return to the second processing specified value N2d+α in a state where the second blowing amount Q2d is maintained in the period X, the controller 18 changes the blowing amount QT from the second blowing amount Q2d to the fourth blowing amount Q4d at the timing T5f. The controller 18 determines whether the detected force N received from the normal substrate WN returns to the second processing specified value N2d+α in the process in which the blowing amount QT increases from the second blowing amount Q2d to the fourth blowing amount Q4d.

At the timing T5g, the detected force N received from the normal substrate WN returns to the second processing specified value N2d+α. Thereafter, at the timing T5h, the blowing amount QT reaches the fourth blowing amount Q4d. In the graph illustrated in (4), the force N received from the normal substrate WN corresponding to the fourth blowing amount Q4d should be larger than the second processing specified value N2d+α, but is converged at the second processing specified value N2d+α by the feedback control. This point is the same as Graph (2) of the first embodiment.

When the detected force N received from the normal substrate WN has returned to the second processing specified value N2d+α, the controller 18 continues the second treating fluid supply processing.

The processing from the timing T6 to the timing T7 is processing of finishing the substrate processing on the normal substrate WN as in Graphs (1) and (2).

In the period Z from the timing T5h to the timing T5z, the controller 18 determines whether the detected force N received from the normal substrate WN returns to the second processing specified value N2d+α while maintaining the fourth blowing amount Q4d. When the force N received from the normal substrate WN detected in the period Z has returned to the second processing specified value N2d+α, the second treating fluid supply processing continues as described above. When the force N received from the normal substrate WN detected in the period Z does not return to the second processing specified value N2d+α, the controller 18 stops the rotation of the plate 32 at the end of the period Z. After stopping the rotation of the plate 32, the controller 18 stops the supply of the nitrogen gas. This makes it possible to prevent the second treating fluid supply processing from continuing in a state where the frictional force between the substrate W and the fixing pin 33 is reduced, that is, in a state where a suction force necessary for supplying the second treating fluid is not applied to the substrate W.

### Effect of Fourth Embodiment

In this manner, for example, when the rotational speed of the plate 32 changes during the supply of the treating fluid in the processing unit 14, the processing specified value changes according to the change in the rotational speed of the plate 32. This makes it possible to determine whether the detected force N received from the substrate W has exceeded the specified value with the value according to the rotation speed of the plate 32.

The processing on the substrate W includes at least first treating fluid supply processing and second treating fluid supply processing subsequent to the first treating fluid supply processing, and the processing specified value is a predetermined rotation specified value and a processing specified value necessary for the second treating fluid supply processing when the processing on the substrate W is changed from the first treating fluid supply processing to the second treating fluid supply processing. This allows the force N received from the substrate W to be a force necessary for the processing (the rotation specified value and the processing specified value) when the detected force N received from the substrate W has fallen below the rotation specified value and the processing specified value necessary for the second treating fluid supply processing when the processing on the substrate W changes from the first treating fluid supply processing to the second treating fluid processing.

The specified value is, for example, a predetermined processing specified value for continuing the second treating fluid supply processing when the processing unit 14 is executing the second treating fluid supply processing on the substrate W. This allows the force N received from the substrate W to be a force necessary for the second treating fluid supply processing (force corresponding to the second treating fluid supply processing) when the detected force N received from the substrate W has fallen below the processing specified value necessary for continuing the second treating fluid supply processing when the processing unit 14 is executing the second treating fluid supply processing.

### Fifth Embodiment

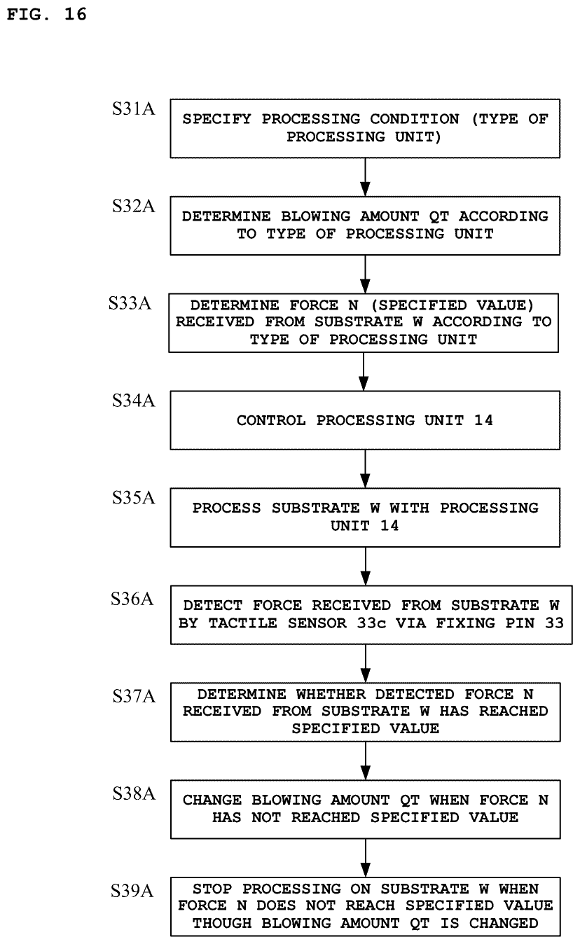

A substrate processing apparatus 1 according to a fifth embodiment will be described with reference to FIG. 16. FIG. 16 is a flowchart illustrating a procedure of control of the controller 18 and operation of the processing unit 14 according to the fifth embodiment.

In the operation example of the processing unit 14 of the sixth embodiment, the controller 18 determines the blowing amount QT and the specified value according to the type of the processing unit 14. The flowchart shown in Step 31A to Step 39A is basically the same as the flowchart shown in Step 31 to Step 39 described with reference to FIG. 13 in the third embodiment. Hereinafter, different points will be mainly described.

The controller 18 adopts the type of the processing unit 14 as a processing condition used for processing the substrate W. The controller 18 acquires the type of the processing unit 14 used for processing the substrate W from, for example, the information regarding the processing recipe of the substrate W stored in the barcode of the carrier C and the storage medium of the controller 18.

The frictional force between the substrate W and the fixing pin 33 may vary depending on the type of the processing unit 14. The type of the processing unit 14 varies depending on processing conditions such as the rotation speed of the plate 32, the type of the treating fluid, and the flow velocity of the treating fluid. When the type of the processing unit 14 changes from the type of the reference processing unit 14, the suction force necessary for performing the processing in the processing unit 14 changes from the suction force with the reference treating fluid.

Even when there are a plurality of types of treating fluids, by setting the blowing amount QT in advance according to the type of the processing unit 14, normally, a sufficient suction force can be applied to the substrate W according to the type of the processing unit 14. However, as described in the first embodiment, a sufficient suction force does not act on the substrate W in some cases. Thus, as in the first embodiment, the controller 18 detects a decrease in frictional force between the substrate W and the fixing pin 33 by detecting the force N that the tactile sensor 33c receives from the substrate W via the fixing pin 33b, and controls the processing unit 14, for example, adjusts the blowing amount QT based on the detection results.

This can change the specified value for determining whether to perform the processing for changing the blowing amount QT according to the type of the processing unit 14. That is, when the frictional force between the substrate W and the fixing pin 33 is reduced, whether to perform the processing for changing the blowing amount QT can be determined according to the type of the treating fluid.

As a result, when an event of decreasing the frictional force between the substrate W and the fixing pin 33 has occurred, it may be determined that the processing of changing the blowing amount QT is performed in a certain type of processing unit 14. However, when the same event has occurred with another type of processing unit 14, it may be determined that the processing of changing the blowing amount QT is not performed. Thus, even though the same event has occurred, the processing can proceed without changing the blowing amount QT in a case of a treating fluid with which the blowing amount QT does not need to be changed.

### Effect of Fifth Embodiment

The specified value is a value determined in advance according to the type of the processing unit 14. This makes it possible to determine whether the detected force received from the substrate W has exceeded a specified value with height according to the type of the processing unit 14.

### Sixth Embodiment

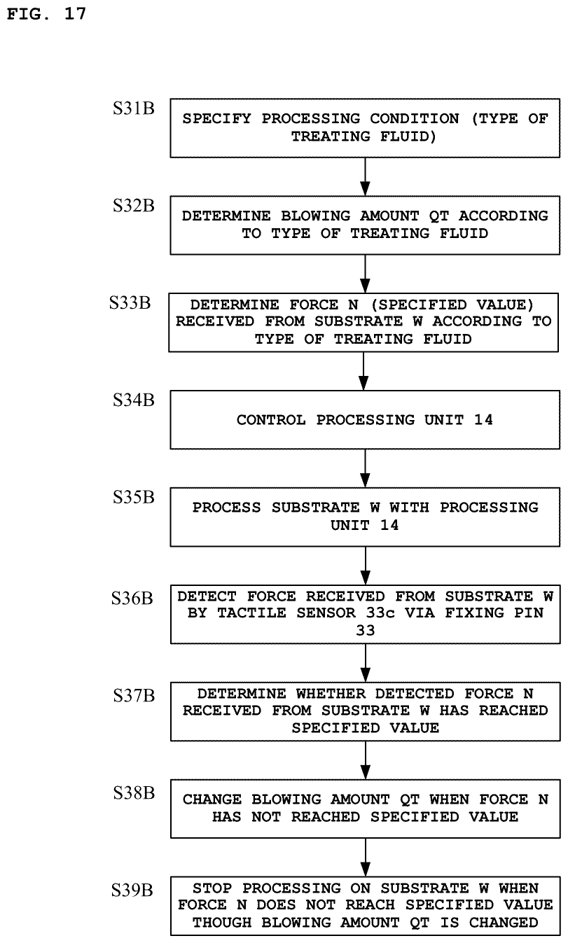

A substrate processing apparatus 1 according to a sixth embodiment will be described with reference to FIG. 17. FIG. 17 is a flowchart illustrating a procedure of control of the controller 18 and operation of the processing unit 14 according to the sixth embodiment.

In the operation example of the processing unit 14 of the sixth embodiment, the controller 18 determines the blowing amount QT and the specified value according to the type of the treating fluid. The flowchart shown in Step 31B to Step 39B is basically the same as the flowchart shown in Step 31 to Step 39 described with reference to FIG. 13 in the third embodiment. Hereinafter, different points will be mainly described.

In the operation example of the processing unit 14 in the sixth embodiment, the controller 18 acquires the type of the treating fluid used for processing the substrate W from, for example, the information regarding the processing recipe of the substrate W stored in the barcode of the carrier C and the storage medium of the controller 18.

The frictional force between the substrate W and the fixing pin 33 may vary depending on the type of the treating fluid from the treating fluid supply part 51. The types of the treating fluids are, for example, pure water. The types of the treating fluid are, for example, treating fluids other than pure water. The treating fluids other than pure water is, for example, a treating fluid with which the frictional force between the substrate W and the fixing pin 33 is reduced as compared with a case where a pure water is supplied. When the treating fluid is changed from the reference treating fluid, the suction force necessary for performing the processing in the processing unit 14 changes from the suction force with the reference treating fluid.

When there are a plurality of types of treating fluids that can be used for the processing on the substrate W, normally, by setting the blowing amount QT in advance according to the type of the treating fluid, a sufficient suction force can be applied to the substrate W according to the type of the treating fluid. However, as described in the first embodiment, a necessary suction force does not act on the substrate W in some cases. Thus, as in the first embodiment, the controller 18 detects a decrease in frictional force between the substrate W and the fixing pin 33 by detecting the force N that the tactile sensor 33c receives from the substrate W via the fixing pin 33b, and controls the processing unit 14, for example, adjusts the blowing amount QT based on the detection results.

This can change the specified value for determining whether to perform the processing for changing the blowing amount QT according to the type of the treating fluid. That is, when the frictional force between the substrate W and the fixing pin 33 is reduced, whether to perform the processing for changing the blowing amount QT can be determined according to the type of the treating fluid.

As a result, when an event of decreasing the frictional force between the substrate W and the fixing pin 33 has occurred, it may be determined that the processing of changing the blowing amount QT is performed with a certain type of treating fluid. However, when the same event has occurred with another type of treating fluid, it may be determined that the processing of changing the blowing amount QT is not performed. Thus, even though the same event has occurred, the processing can proceed without changing the blowing amount QT in a case where the blowing amount QT does not need to be changed according to the another type of treating fluid.

### Effect of Sixth Embodiment

The treating fluid supply unit 51 that supplies a treating fluid to the substrate W supported by the fixing pins 33b is provided, and the specified value is a value determined in advance according to the type of the treating fluid. This makes it possible to determine whether the detected force N received from the substrate W has exceeded a specified value with height according to the type of the treating fluid of the flow amount of the treating fluid.

The present invention is not limited to the first to sixth embodiments, and can be modified as follows.
(1) In the first embodiment described above, the specified value of the substrate W is determined according to the shape of the substrate W. In the second embodiment described above, the specified value is determined according to the type of the film to be formed on the substrate W. In the third and fourth embodiments described above, the specified value of the substrate W is determined according to the rotation speed of the plate 32 as the substrate processing condition, for example. In the fifth and sixth embodiments described above, the specified value of the substrate W is determined according to the type of the processing unit 14 and the type of the treating fluid. However, the present invention is not limited to these embodiments. For example, the controller 18 may determine the specified value according to at least one condition of the shape of the substrate W, the type of the film to be formed on the substrate W, the rotation speed of the plate 32, the type of the processing unit 14, and the type of the treating fluid.

For example, in the controller 18, a predetermined specified value in a certain processing unit 14 may be provided for the shape of the substrate W, the type of the film, the rotation speed of the plate 32, the type of the treating fluid, or the flow velocity of the treating fluid. When the substrate W is processed according to the shape of the substrate W, the type of the film, the rotation speed of the plate 32, the type of the treating fluid, or the flow velocity of the treating fluid different from the specified value, the controller 18 may adjust the specified value based on the detected force N received from the substrate W.
(2) In the first embodiment, the shape of the substrate W is detected by the barcode reader 4 or at least one of the shape detectors 13 and 63. In the second embodiment, the type of the film formed on the substrate W is detected by the barcode reader 4. In the third and fourth embodiments, the rotation speed of the plate 32 as the substrate processing condition is acquired from the processing recipe stored in the storage medium of the controller 18, for example. In the fifth and sixth embodiments described above, the type of the processing unit 14 and the type of the treating fluid are acquired from the processing recipe stored in the storage medium of the controller 18. However, the present invention is not limited to these embodiments. For example, the controller 18 may acquire information for determining these specified values from the information input by the operator via the input part 17.
(3) In the first to sixth embodiments described above, when the detected force N received from the substrate W does not reach the specified value, it is finally determined whether the force reaches the specified value through the feedback control. However, the present invention is not limited to these embodiments. For example, when the detected force N received from the substrate W has significantly decreased, the controller 18 may finally determine that the force does not reach the specified value without performing the feedback control. The case where it is finally determined that the force does not reach the specified value is a case where the substrate W is not normally supported by the fixing pin 33. Specifically, for example, this is a case where the substrate W is not normally supported by the fixing pins 33 because of cracking or the like of the substrate W during processing on the substrate W. For example, this is a case where the substrate W is not broken, but the substrate W is detached from the fixing pin 33. The case where the detected force N received from the substrate W has significantly decreased is, for example, a case where the controller 18 determines that the detected force N received from the substrate W is 0 or a value close to 0. The above two cases correspond to this.

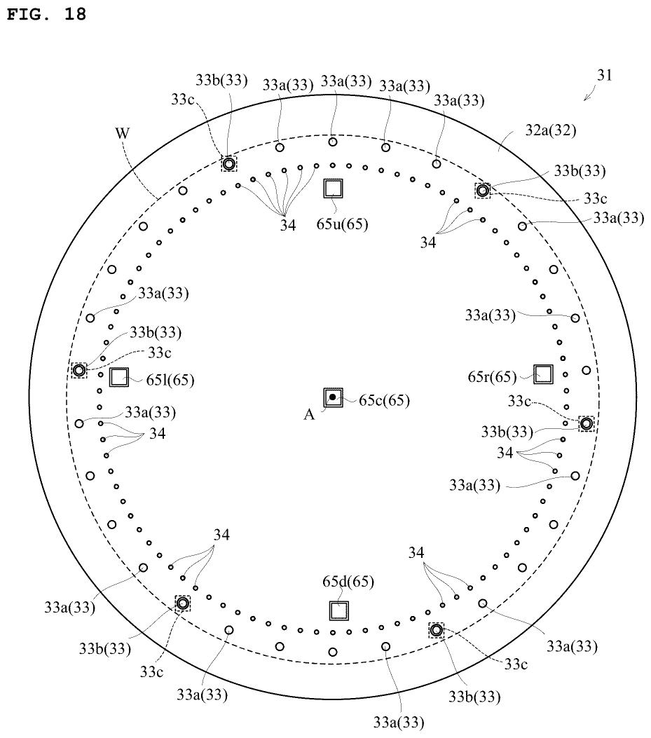

With such a configuration, the controller 18 can determine whether the substrate W is normally placed on the fixing pin 33 by using the detected force N received from the substrate W.
(4) In the sixth embodiment, the controller 18 determines the specified value according to the type of the treating fluid. However, the present invention is not limited to this configuration. The controller 18 may determine the specified value according to the flow rate of the treating fluid. There is a case where the flow of the gas supplied between the lower surface 26 of the substrate W and the upper surface 32a of the plate 32 is changed because of the end of the treating fluid supplied to the upper surface 27 of the substrate W. Because of the flow change, the suction force acting on the substrate W may change. Because of the flow change, the frictional force between the fixing pin 33 and the substrate W may decrease. The present invention is effective in such a case.
(5) Instead of the controller determining that the detected force N received from the substrate W is 0 or a value close to 0, a sensor that detects occurrence of an event in which the detected force N received from the substrate W becomes 0 or a value close to 0 may be provided. This will be described with reference to FIG. 18. FIG. 18 is a top view of the plate 32 according to a modification.

For example, a proximity sensor 65 capable of detecting the presence or absence of the substrate W is provided on the upper surface 32a of the plate 32. The proximity sensor 65 includes an infrared light emitting element such as an infrared light emitting diode and a light receiving element such as a photodiode. The infrared light emitting element emits infrared light toward the lower surface 26 of the substrate W placed on the fixing pin 33. The light receiving element receives infrared rays reflected from the lower surface 26 of the substrate W placed on the fixing pin 33. When there is a detection signal from the light receiving element, the controller 18 determines that the substrate W is normally placed on the fixing pin 33. When there is no detection signal from the light receiving element, the controller 18 determines that the substrate W is not normally placed on the fixing pin 33.

The proximity sensor 65c is provided at the center of the upper surface 32a of the plate 32, for example. With this configuration, when the substrate W is broken in half at the central portion, the proximity sensor 65c is exposed from the gap of the broken substrate W. As a result, when the substrate W is completely damaged, the damage can be quickly detected without undergoing feedback control.

Proximity sensors 65r, 651, 65u, and 65d are provided at the right side, the left side, the upper side, and the lower side of the upper surface 32a of the plate 32, for example. The proximity sensors 65r, 651, 65u, and 65d are provided in the vicinity of the gas outlet 34 and on the side close to the rotation axis A. For example, the substrate W is detached from the fixing pin 33 and horizontally moves toward the left side of the rotation axis A. At this time, the proximity sensor 65r is exposed. That is, the proximity sensor 65r detects horizontal movement of the substrate W in the left direction. In this manner, the proximity sensors 65r, 651, 65u, and 65d detect that the substrate W is detached from the fixing pin 33 and horizontally moved to any of the upper, lower, left, and right of the rotation axis A.

With this configuration, when the substrate W is detached from the fixing pin 33 and the detected force N received from the substrate W becomes 0 or a value close to 0, it is possible to perform processing such as rapidly stopping the rotation of the plate 32. The plate 32 includes both the proximity sensor 65c and the proximity sensors 65r, 651, 65u, and 65d, but it may include only one of them.

When the force received from the substrate W is less than the specified value although the controller 18 has adjusted the flow rate of the gas blown out from the gas outlet 14 to be equal to or more than the specified value, the rotation drive of the rotation driver 45 stops. Here, the reason of the force received from the substrate W being less than the specified value even though the flow rate of the gas blown out from the gas outlet 14 is adjusted to be equal to or larger than the specified value may be that the substrate W is not supported by the fixing pins 33 or the substrate supported by the fixing pins 33 is damaged. In such a case, it is possible to reduce unnecessary processing time by stopping the rotation drive of the rotation driver 45.
(6) In the first embodiment described above, an example of the support in the present invention is the fixing pin 33. However, the support in the present invention is not limited to this. The support may be a support having a shape different from that of the fixing pin 33. For example, the support may include a portion that abuts on the peripheral edge 23 of the substrate W. Unless the support is configured to completely grip the peripheral edge 23 of the substrate W, there is a possibility that the substrate W is detached from the support because of a decrease in frictional force between the support and the substrate W. By applying the present invention, it becomes easy to prevent the substrate W from being completely detached from the support.
(7) In the first embodiment described above, an example of the detector in the present invention is the tactile sensor 33c. However, the detector in the present invention is not limited to this. The detector may be a detector different from the tactile sensor 33c. The detector may be a weight sensor that detects the weight of the substrate W applied when the substrate W is placed on the fixing pin 33b. The detector may be a pressure sensor that detects the pressure from the substrate W applied when the substrate W is placed on the fixing pin 33b. The weight sensor and the pressure sensor detect the force N received from the substrate W.
(8) In the first embodiment described above, the tactile sensor 33c that is an example of the detector in the present invention is attached for each fixing pin 33b. However, the method for attaching the detector in the present invention is not limited to this. The tactile sensor 33c may be collectively attached to a plurality of fixing pins 33b. For example, a coupling component that couples the base ends of the plurality of fixing pins 33b is provided inside the plate 32. The tactile sensor 33c is attached to the coupling component. The present invention can also be realized with such a configuration.
(9) In the first to sixth embodiments described above, after the substrate W is placed on the fixing pin 33, the controller 18 always performs the feedback control until the processing on the substrate W ends. However, the present invention is not limited to this configuration. For example, the controller 18 may perform the feedback control only during a period until the rotation speed of the plate 32 reaches the rotation speed necessary for the processing on the substrate W. Alternatively, the controller 18 may perform the feedback control only during a period after the rotation speed of the plate 32 has reached the rotation speed necessary for the processing on the substrate W.
(10) In the first embodiment described above, for the shape of the substrate W for determining the specified value, whether the substrate W is the normal substrate WN or the special substrate WS is determined by the thicknesses of the main portion 22 and the peripheral edge 23 of the substrate W. However, the shape of the substrate W for determining the specified value may be determined based on the contour of the substrate W acquired by a two-dimensional image sensor. For example, the substrate is an umbrella-shaped substrate having a curved portion protruding upward or a bowl-shaped substrate having a curved portion protruding downward. Not only for the special substrate WS as in the first embodiment but also for the umbrella-shaped substrate and the bowl-shaped substrate, the blowing amount QT corresponding to each shape and a prescribed value corresponding to the blowing amount are determined.

For the above-described embodiments and each modified embodiment, each configuration may be appropriately changed by further replacing or combining each configuration with a configuration of another modified embodiment.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus, the apparatus comprising:
a processing unit that processes a substrate; and
a controller that controls the processing unit,
wherein
the processing unit includes:
a plate having an upper surface;
a rotation driver that rotates the plate;
a support that protrudes upward from the upper surface of the plate, is in contact with at least one of a lower surface of the substrate and an edge of the substrate, and supports the substrate at a position higher than the upper surface of the plate;
a gas outlet that is formed on the upper surface of the plate and blows gas upward;
a blowing adjuster that adjusts a flow rate of the gas blown out from the gas outlet; and
a detector that detects a force received from the substrate when a suction force according to Bernoulli's principle acts on the substrate supported by the support, and
the controller controls the processing unit based on information on the force received from the substrate detected by the detector.

2. The substrate processing apparatus according to claim 1, wherein
the detector detects a pressing force with which the substrate presses the support when the suction force acts on the substrate supported by the support as the force received from the substrate, and
the controller controls the processing unit based on information on the pressing force detected by the detector.

3. The substrate processing apparatus according to claim 2, wherein the detector is attached to the support.

4. The substrate processing apparatus according to claim 1, wherein
the detector detects a pressing force with which the support presses the plate when the suction force acts on the substrate supported by the support as the force received from the substrate, and
the controller controls the processing unit based on information on the pressing force detected by the detector.

5. The substrate processing apparatus according to claim 4, wherein the detector is attached to the plate.

6. The substrate processing apparatus according to claim 1, wherein the controller changes the flow rate of the gas blown out from the gas outlet based on information on the force received from the substrate.

7. The substrate processing apparatus according to claim 1, wherein when the force received from the substrate is less than a specified value, the controller adjusts the flow rate of the gas blown out from the gas outlet such that the force received from the substrate is equal to or larger than the specified value.

8. The substrate processing apparatus according to claim 7, wherein the specified value is a value determined in advance for the processing unit to start processing on the substrate.

9. The substrate processing apparatus according to claim 7, wherein the specified value is a value determined in advance necessary for processing on the substrate when the processing unit is executing the processing on the substrate.

10. The substrate processing apparatus according to claim 9, wherein
the processing on the substrate includes at least first processing and second processing subsequent to the first processing, and
the specified value is a value determined in advance necessary for the second processing when the processing on the substrate is changed from the first processing to the second processing.

11. The substrate processing apparatus according to claim 7, wherein the specified value is a value determined in advance for a type of a shape of the substrate.

12. The substrate processing apparatus according to claim 7, wherein the specified value is a value determined in advance according to a rotation speed of the plate.

13. The substrate processing apparatus according to claim 12, wherein when the rotation speed of the plate changes during processing in the processing unit, the specified value changes according to a change in the rotation speed of the plate.

14. The substrate processing apparatus according to claim 7, wherein
the substrate is formed with a processing film,
the support supports a surface on which the processing film is formed, and
the specified value is a value determined in advance according to a type of the processing film.

15. The substrate processing apparatus according to claim 7,
the apparatus comprising a supply part that supplies a treating fluid to the substrate supported by the support,
wherein the specified value is a value determined in advance according to a type of the treating fluid or a flow rate of the treating fluid.

16. The substrate processing apparatus according to claim 15, wherein when the type of the treating fluid or the flow rate of the treating fluid changes during processing in the processing unit, the specified value changes according to a change in the type of the treating fluid or the flow rate of the treating fluid.

17. The substrate processing apparatus according to claim 7, wherein the specified value is a value determined in advance according to a type of the processing unit.

18. The substrate processing apparatus according to claim 7, wherein when the force received from the substrate is less than the specified value though the flow rate of the gas blown out from the gas outlet is adjusted to have a value equal to or larger than the specified value, the controller stops a rotation of the rotation driver.
